(19) United States
(12) Patent Application Publication
(10) Pub. No.: US 2026/0123016 A1
(43) Pub. Date: Apr. 30, 2026

(54) SEMICONDUCTOR DEVICE

(71) Applicant: SAMSUNG ELECTRONICS CO., LTD., Suwon-si (KR)

(72) Inventors: Min Gyu KIM, Suwon-si (KR); Geun Woo KIM, Suwon-si (KR); Wan Don KIM, Suwon-si (KR); Sun Gyu CHOI, Suwon-si (KR); Sang Hoon JEONG, Suwon-si (KR); Hye Won JEONG, Suwon-si (KR)

(21) Appl. No.: 19/231,824

(22) Filed: Jun. 9, 2025

(30) Foreign Application Priority Data
Oct. 28, 2024 (KR) 10-2024-0148521

(51) Int. Cl. H10D 64/62; H10D 30/00

(52) U.S. Cl. CPC H10D 64/62; H10D 30/501

(57) ABSTRACT

A semiconductor device includes, a gate structure on an active pattern and including a gate electrode and a gate capping pattern; a source/drain pattern; a contact silicide film on the source/drain pattern and defining a contact recess; a source/drain contact connected to the source/drain pattern; an etching stop film on an upper surface of the gate capping pattern and an upper surface of the source/drain contact; and a first via pattern that extends through the etching stop film, is connected to the source/drain contact, and includes a first metal. The source/drain contact includes a lower conductive contact pattern, a first contact metal pattern including a second metal, and a second contact metal pattern including a third metal. The third metal is different from the first metal and the second metal, and the second contact metal pattern is between the first contact metal pattern and the first via pattern.

### CROSS-REFERENCE TO RELATED APPLICATION(S)

This application claims priority under 35 U.S.C. § 119 to Korean Patent Application No. 10-2024-0148521 filed on Oct. 28, 2024 in the Korean Intellectual Property Office, the disclosure of which is herein incorporated by reference in its entirety.

### BACKGROUND

As one of scaling technologies for increasing density of a semiconductor device, a multi gate transistor has been proposed. In an example multi gate transistor, a multi-channel active pattern (or a silicon body) having a fin or nanowire shape is formed on a substrate and a gate is formed on a surface of the multi-channel active pattern.

As a pitch size of semiconductor devices decreases, it is desired to decrease capacitance between contacts in the semiconductor device and electrical stability.

### SUMMARY

Aspects of the present disclosure provide a semiconductor device that may improve element performance and reliability.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a semiconductor device comprising, a gate structure which is disposed on an active pattern, and includes a gate electrode and a gate capping pattern, the gate capping pattern being disposed on the gate electrode, a source/drain pattern which is disposed on at least one side of the gate structure, a contact silicide film which is disposed on the source/drain pattern, and defines a contact recess, a source/drain contact which fills the contact recess, and is connected to the source/drain pattern, an etching stop film which is disposed on an upper surface of the gate capping pattern and an upper surface of the source/drain contact and a first via pattern which penetrates the etching stop film, is connected to the source/drain contact, and is formed of a first metal, wherein the source/drain contact includes a lower conductive contact pattern, a first contact metal pattern formed of a second metal, and a second contact metal pattern formed of a third metal, the first contact metal pattern and the second contact metal pattern are disposed on the lower conductive contact pattern, the third metal is different from the first metal and the second metal, and the second contact metal pattern is disposed between the first contact metal pattern and the first via pattern, and is in contact with the first via pattern.

According to another aspect of the present disclosure, there is provided a semiconductor device comprising, a gate structure which is disposed on an active pattern, and includes a gate electrode and a gate capping pattern, the gate capping pattern being disposed on the gate electrode, a source/drain pattern which is disposed on at least one side of the gate structure, a source/drain contact which is disposed on the source/drain pattern and connected to the source/drain pattern and a molybdenum via pattern which is disposed on the source/drain contact, and is in contact with an upper surface of the source/drain contact, wherein the source/drain contact includes a lower conductive contact pattern, a contact metal pattern formed of a first metal, and a tungsten contact pattern, the contact metal pattern is disposed between the tungsten contact pattern and the lower conductive contact pattern, and at least a part of an upper surface of the source/drain contact is defined by the tungsten contact pattern.

According to another aspect of the present disclosure, there is provided a semiconductor device comprising, an active pattern which includes a lower pattern, and a sheet pattern on the lower pattern, a gate structure which includes a gate electrode and a gate capping pattern on the active pattern, the gate electrode surrounding the sheet pattern, and the gate capping pattern being disposed on the gate electrode, a source/drain pattern which is disposed on at least one side of the gate structure, a source/drain contact which is connected to the source/drain pattern, on the source/drain pattern, an etching stop film which is disposed on an upper surface of the gate capping pattern and the upper surface of the source/drain contact and a molybdenum via pattern which penetrates the etching stop film, and is in contact with the upper surface of the source/drain contact, wherein the source/drain contact includes a lower conductive contact pattern, a molybdenum contact pattern, and a tungsten contact pattern, and at least a part of the upper surface of the source/drain contact is defined by the tungsten contact pattern.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail example implementations thereof with reference to the attached drawings, in which:

FIG. 1 is an example layout diagram for explaining the semiconductor device according to some implementations.

FIG. 2 is a cross-sectional view taken along A-A of FIG. 1.

FIG. 3 is a cross-sectional view taken along B-B of FIG. 1.

FIG. 4 is a cross-sectional view taken along C-C of FIG. 1.

FIG. 5 is a graph which compares the resistivity of an upper conductive film depending on a material included in a lower film.

FIGS. 6 and 7 are diagrams for explaining a semiconductor device according to some implementations.

FIGS. 8 and 9 are diagrams for explaining a semiconductor device according to some implementations.

FIGS. 10 and 11 are diagrams for explaining a semiconductor device according to some implementations.

FIGS. 12 to 14 are diagrams for explaining a semiconductor device according to some implementations.

FIGS. 15 and 16 are diagrams for explaining a semiconductor device according to some implementations.

FIG. 17 is a diagram for explaining a semiconductor device according to some implementations.

FIGS. 18 to 21 are diagrams for explaining a semiconductor device according to some implementations.

FIGS. 22 to 24 are diagrams for explaining a semiconductor device according to some implementations.

FIGS. 25 to 31 are intermediate stage diagrams for explaining a method for fabricating a semiconductor device according to some implementations.

FIGS. 32 to 35 are intermediate stage diagrams for explaining a method for fabricating a semiconductor device according to some implementations.

FIGS. 36 to 40 are intermediate stage diagrams for explaining a method for fabricating a semiconductor device according to some implementations.

### DETAILED DESCRIPTION

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Although drawings of the semiconductor device according to some implementations show a fin-type transistor (FinFET) including a channel region of a fin-type pattern shape, a transistor including a nanowire or a nanosheet, and a MBCFET™ (Multi-Bridge Channel Field Effect Transistor) as an example, the implementation is not limited thereto. The semiconductor device according to some implementations may, of course, include a tunneling transistor (tunneling FET) or a three-dimensional (3D) transistor. The semiconductor device according to some implementations may, of course, include a planar transistor. In addition, the technical idea of the present disclosure may be applied to a transistor based on two-dimensional material (2D material based FETs) and a heterostructure thereof.

Further, the semiconductor device according to some implementations may also include a bipolar junction transistor, a laterally diffused metal oxide semiconductor (LDMOS), or the like.

In some implementations, the semiconductor device includes multi gate transistors with multi-channel active patterns. Since a multi gate transistor utilizes a three-dimensional channel, scaling may be performed. Further, with a same gate length of the multi gate transistor, the current control capability may be improved. Furthermore, a short channel effect (SCE), which relates to the influence on potential of a channel region by a drain voltage, may be reduced.

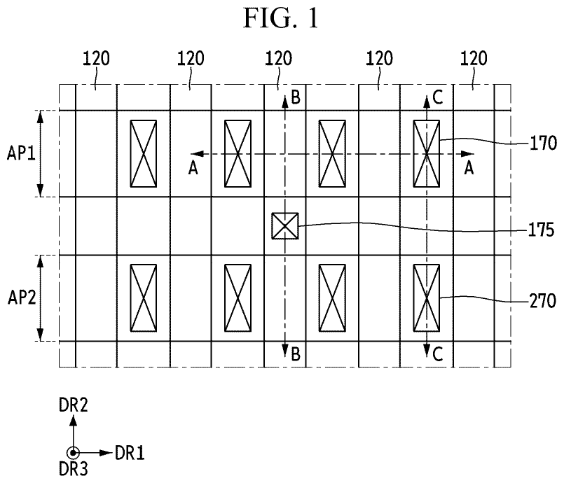

A semiconductor device according to some implementations will be described referring to FIGS. 1 to 5.

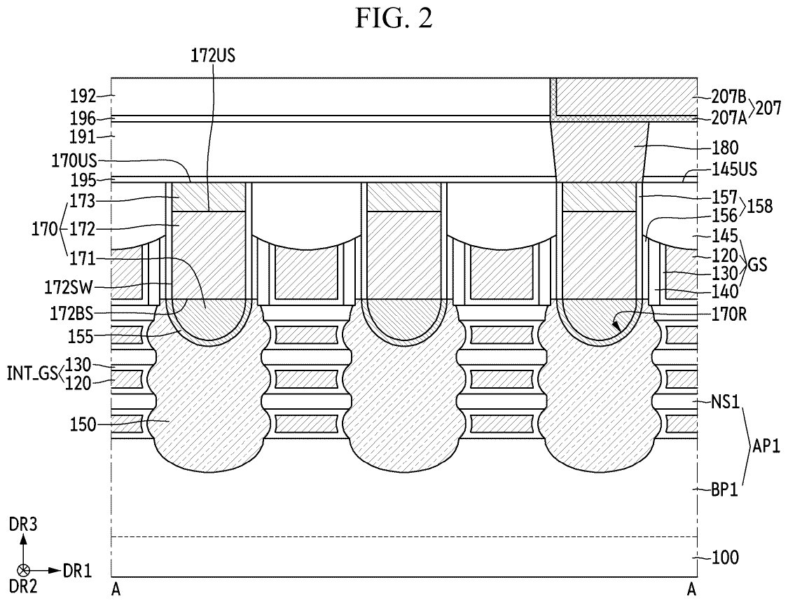

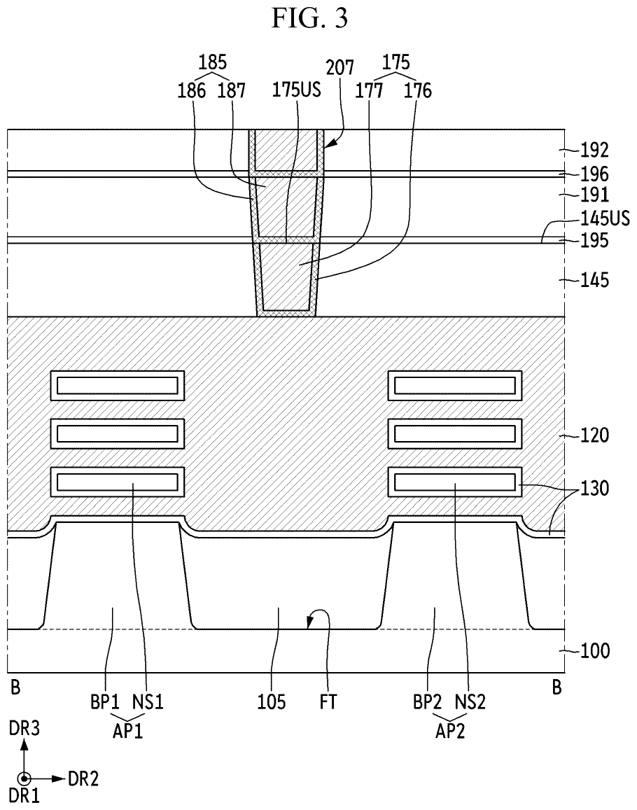

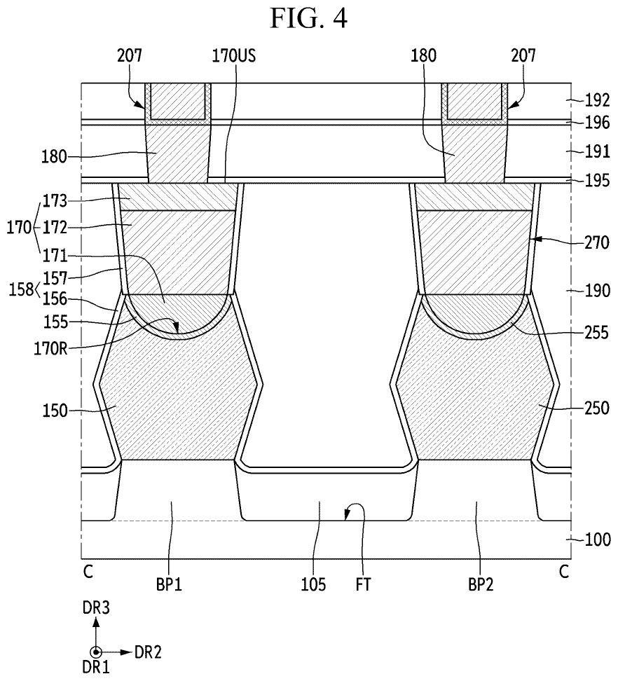

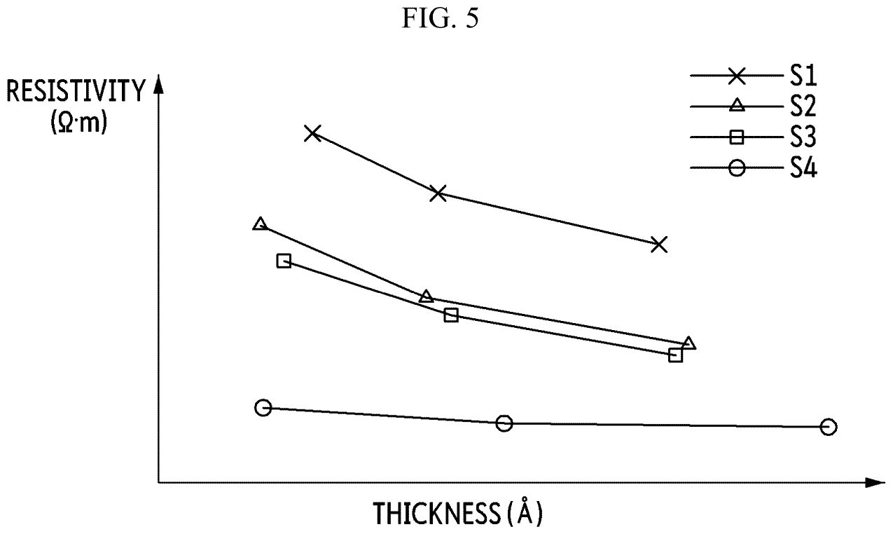

FIG. 1 is an example layout diagram for explaining the semiconductor device according to some implementations. FIG. 2 is a cross-sectional view taken along A-A of FIG. 1. FIG. 3 is a cross-sectional view taken along B-B of FIG. 1. FIG. 4 is a cross-sectional view taken along C-C of FIG. 1. FIG. 5 is a graph which compares the resistivity of an upper conductive film depending on a material included in a lower film.

For convenience of explanation, FIG. 1 does not show a source/drain via 180, a gate via 185, and a first wiring line 207. Also, although a gate contact 175 is shown to be disposed on one first gate electrode 120 among a plurality of first gate electrodes 120, this is only for explanation, and the implementation is not limited thereto.

Referring to FIGS. 1 to 5, the semiconductor device according to some implementations may include a first active pattern AP1, a second active pattern AP2, at least one or more first gate electrodes 120, first and second source/drain contacts 170 and 270, a gate contact 175, a source/drain via pattern 180, a gate via pattern 185, and a wiring line 207.

As an example, the substrate 100 may be bulk silicon or silicon-on-insulator (SOI). In contrast, the substrate 100 may be a silicon substrate or may include other materials, for example, but not limited to, silicon germanium, silicon germanium on insulator (SGOI), indium antimonide, lead telluride, indium arsenide, indium phosphide, gallium arsenide, or gallium antimonide. As another example, the substrate 100 may be formed of an insulating material.

The first active pattern AP1 and the second active pattern AP2 may be disposed on the substrate 100. The first and second active patterns AP1 and AP2 may each extend long in a first direction DR1. The first and second active patterns AP1 and AP2 may be disposed to be spaced apart from each other in a second direction DR2. For example, the first direction DR1 is a direction that intersects the second direction DR2.

As an example, one of the first active pattern AP1 and the second active pattern AP2 may be a PMOS formation region, and the other may be an NMOS formation region. As another example, the first active pattern AP1 and the second active pattern AP2 may be the NMOS formation region. As yet another example, the first active pattern AP1 and the second active pattern AP2 may be the PMOS formation region.

As an example, the first active pattern AP1 and the second active pattern AP2 may be disposed in a logic region. As another example, the first active pattern AP1 and the second active pattern AP2 may be disposed in an SRAM region. As yet another example, the first active pattern AP1 and the second active pattern AP2 may be disposed in an I/O region.

The first active pattern AP1 and the second active pattern AP2 may be, for example, a multi-channel active pattern. The first active pattern AP1 may include a first lower pattern BP1 and a plurality of first sheet patterns NS1. The second active pattern AP2 may include a second lower pattern BP2 and a plurality of second sheet patterns NS2.

Each of the first lower pattern BP1 and the second lower pattern BP2 may protrude from the substrate 100. Each of the first lower pattern BP1 and the second lower pattern BP2 may extend long in the first direction DR1.

The first lower pattern BP1 may be spaced apart from the second lower pattern BP2 in the second direction DR2. The first lower pattern BP1 and the second lower pattern BP2 may be separated by a fin trench FT extending in the first direction DR1.

The plurality of first sheet patterns NS1 may be disposed on an upper surface of the first lower pattern BP1. The plurality of first sheet patterns NS1 may be spaced apart from the first lower pattern BP1 in a third direction DR3. Each of the first sheet patterns NS1 may be spaced apart in the third direction DR3. The third direction DR3 may be a direction that intersects the first direction DR1 and the second direction DR2. For example, the third direction DR3 may be a thickness direction of the substrate 100. The first direction DR1 may be a direction that intersects the second direction DR2.

The plurality of second sheet patterns NS2 may be disposed on the upper surface of the second lower pattern BP2. The plurality of second sheet patterns NS2 may be spaced apart from the second lower pattern BP2 in the third direction DR3. Each of the second sheet patterns NS2 may be spaced apart in the third direction DR3.

Although each of the three first sheet patterns NS1 and the three second sheet patterns NS2 is shown as being disposed in the third direction DR3, this is only for convenience of explanation, and the implementation is not limited thereto.

As an example, the first lower pattern BP1 and the second lower pattern BP2 may be formed by etching a part of the substrate 100, and may include an epitaxial layer that is grown from the substrate 100. Each of the first lower pattern BP1 and the second lower pattern BP2 may include silicon or germanium, which is an elemental semiconductor material. Also, the first lower pattern BP1 and the second lower pattern BP2 may include a compound semiconductor, and may include, for example, a group IV-IV compound semiconductor or a group III-V compound semiconductor.

The group IV-IV compound semiconductor may include, for example, a binary compound or a ternary compound including at least two or more of carbon (C), silicon (Si), germanium (Ge) and tin (Sn), or a compound obtained by doping these elements with a group IV element.

The group III-V compound semiconductor may be, for example, at least one of a binary compound, a ternary compound or a quaternary compound formed by combining at least one of aluminum (Al), gallium (Ga) and indium (In) as a group III element with one of phosphorus (P), arsenic (As) and antimony (Sb) as a group V element.

As another example, the first lower pattern BP1 and the second lower pattern BP2 may be formed by filling a space in which a pattern including a semiconductor material is removed with an insulating material. The first lower pattern BP1 and the second lower pattern BP2 may each include an insulating material.

Each of the first sheet pattern NS1 and the second sheet pattern NS2 may include one of silicon or germanium which is the elemental semiconductor materials, a group IV-IV compound semiconductor or a group III-V compound semiconductor. When the first lower pattern BP1 includes a semiconductor material, the first sheet pattern NS1 may include the same material as the first lower pattern BP1, and may include a material different from the first lower pattern BP1. Similarly, when the second lower pattern BP2 includes a semiconductor material, the second sheet pattern NS2 may include the same material as the second lower pattern BP2, and may include a different material from the second lower pattern BP2.

In the semiconductor device according to some implementations, the first lower pattern BP1 and the second lower pattern BP2 are silicon lower patterns including silicon, and the first sheet pattern NS1 and the second sheet pattern NS2 may be silicon sheet patterns including silicon.

For example, a width of the first sheet pattern NS1 in the second direction DR2 may be increased or decreased in proportion to the width of the first lower pattern BP1 in the second direction DR2. As an example, although the width in the second direction DR2 of the first sheet patterns NS1, which are stacked in the third direction DR3, is shown as being the same, this is only for convenience of explanation, and the implementation is not limited thereto. Unlike the shown example, the width in the second direction DR2 of the first sheet patterns NS1 stacked in the third direction DR3 may decrease, as it goes away from the first lower pattern BP1.

A field insulating film 105 may be formed on the substrate 100. The field insulating film 105 may fill at least a part of the fin trench FT.

The field insulating film 105 may be disposed on a side wall of the first lower pattern BP1 and a side wall of the second lower pattern BP2. The field insulating film 105 is not disposed on the upper surface of the first lower pattern BP1 and the upper surface of the second lower pattern BP2.

As an example, the field insulating film 105 may entirely cover the side wall of the first lower pattern BP1. Unlike the shown example, the field insulating film 105 may cover a part of the side wall of the first lower pattern BP1 and/or a part of the side wall of the second lower pattern BP2. In such a case, when the first lower pattern BP1 is taken as an example, a part of the first lower pattern BP1 may protrude in the third direction DR3 beyond the upper surface of the field insulating film 105.

Each of the first sheet patterns NS1 and each of the second sheet patterns NS2 are disposed to be higher than the upper surface of the field insulating film 105. The field insulating film 105 may include, for example, an oxide film, a nitride film, an oxynitride film or a combined film thereof. Although the field insulating film 105 is shown as being a single film, this is only for convenience of explanation, and the implementation is not limited thereto.

At least one or more gate structures GS may be disposed on the substrate 100. For example, at least one or more gate structures GS may be disposed on the field insulating film 105. The gate structures GS may extend in the second direction DR2. Adjacent gate structures GS may be spaced apart from each other in the first direction DR1.

The gate structure GS may be disposed on the first active pattern AP1 and the second active pattern AP2. The gate structure GS may intersect the first active pattern AP1 and the second active pattern AP2.

Although the gate structure GS is shown as being disposed across the first active pattern AP1 and the second active pattern AP2, this is only for convenience of explanation, and the implementation is not limited thereto. That is, a part of the gate structure GS may be separated into two portions and disposed on the first active pattern AP1 and the second active pattern AP2.

The gate structure GS may intersect the first lower pattern BP1 and the second lower pattern BP2. The gate structure GS may surround the first sheet pattern NS1 and the second sheet pattern NS2.

The gate structure GS may include a first gate electrode 120, a first gate insulating film 130, a first gate spacer 140, and a gate capping pattern 145.

The gate structure GS may include an inner gate structure INT_GS which is disposed between the first sheet patterns NS1 adjacent to each other in the third direction DR3, and between the first lower pattern BP1 and the first sheet pattern NS1. The inner gate structure INT_GS may include a first gate electrode 120 and a first gate insulating film 130 which are disposed between the adjacent first sheet patterns NS1, and between the first lower pattern BP1 and the first sheet pattern NS1. Although not shown, the inner gate structure INT_GS may be disposed between the second sheet patterns NS2 adjacent to each other in the third direction DR3, and between the second lower pattern BP2 and the second sheet pattern NS2.

The first gate electrode 120 may be disposed on the first lower pattern BP1 and the second lower pattern BP2. The first gate electrode 120 may intersect the first lower pattern BP1 and the second lower pattern BP2. The first gate electrode 120 may surround the first sheet pattern NS1. The first gate electrode 120 may surround the second sheet pattern NS2.

The upper surface of the first gate electrode 120 may be a concave curved surface that is recessed toward the upper surface of the first active pattern AP1, but is not limited thereto. That is, unlike the shown example, the upper surface of the first gate electrode 120 may be a flat plane. For example, the upper surface of the first active pattern AP1 may be an upper surface of the first sheet pattern NS1 disposed at the uppermost part of the first sheet pattern NS1.

The first gate electrode 120 may include at least one of a metal, a metal alloy, a conductive metal nitride, a metal silicide, a doped semiconductor material, a conductive metal carbonitride, a conductive metal carbide, a conductive metal oxide, or a conductive metal oxynitride. The first gate electrode 120 may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof. Although the conductive metal oxide and the conductive metal oxynitride may include, but not limited to, an oxidized form of the aforementioned materials.

The first gate electrode 120 may be disposed on both sides of a first source/drain pattern 150, which will be described below. The gate structure GS may be disposed on both sides of the first source/drain pattern 150 in the first direction DR1.

As an example, both the first gate electrodes 120 disposed on both sides of the first source/drain pattern 150 may be normal gate electrodes used as gates of transistors. As another example, although the first gate electrode 120 disposed on one side of the first source/drain pattern 150 may be used as a gate of a transistor, the first gate electrode 120 disposed on the other side of the first source/drain pattern 150 may be a dummy gate electrode.

Although not shown, the first gate electrode 120 may be disposed on both sides of a second source/drain pattern 250, which will be described below. The gate structure GS may be disposed on both sides of the second source/drain pattern 250 in the first direction DR1.

The first gate insulating film 130 may extend along an upper surface of the field insulating film 105, an upper surface of the first lower pattern BP1, and an upper surface of the second lower pattern BP2. The first gate insulating film 130 may surround the first sheet pattern NS1. The first gate insulating film 130 may surround the second sheet pattern NS2. The first gate insulating film 130 may be disposed along the periphery of the first sheet pattern NS1 and the periphery of the second sheet pattern NS2. The first gate electrode 120 is disposed on the first gate insulating film 130. The first gate insulating film 130 may be disposed between the first gate electrode 120 and the first sheet pattern NS1, and between the first gate electrode 120 and the second sheet pattern NS2.

The first gate insulating film 130 may include silicon oxide, silicon oxynitride, silicon nitride or a high dielectric constant material having a dielectric constant larger than that of silicon oxide. The high dielectric constant material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide or lead zinc niobate.

Although the first gate insulating film 130 is shown as being a single film, this is only for convenience of explanation, and the implementation is not limited thereto. The first gate insulating film 130 may include a plurality of films. The first gate insulating film 130 may include an interfacial layer disposed between the first sheet pattern NS1 and the first gate electrode 120, and between the second sheet pattern NS2 and the first gate electrode 120, and a high dielectric constant insulating film.

The semiconductor device according to some implementations may include a NC (Negative Capacitance) FET using a negative capacitor. For example, the first gate insulating film 130 may include a ferroelectric material film having ferroelectric properties, and a paraelectric material film having paraelectric properties.

The ferroelectric material film may have a negative capacitance, and the paraelectric material film may have a positive capacitance. For example, if two or more capacitors are connected in series and the capacitance of each capacitor has a positive value, the overall capacitances decrease from the capacitance of each of the individual capacitors. On the other hand, if at least one of the capacitances of two or more capacitors connected in series has a negative value, the overall capacitances may be greater than an absolute value of each of the individual capacitances, while having a positive value.

When the ferroelectric material film having the negative capacitance and the paraelectric material film having the positive capacitance are connected in series, the overall capacitance values of the ferroelectric material film and the paraelectric material film connected in series may increase. By the use of the increased overall capacitance value, a transistor including the ferroelectric material film may have a subthreshold swing (SS) under 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, or lead zirconium titanium oxide. Here, as an example, the hafnium zirconium oxide may be a material obtained by doping hafnium oxide with zirconium (Zr). As another example, the hafnium zirconium oxide may be a compound of hafnium (Hf), zirconium (Zr), and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr) or tin (Sn). The type of dopant included in the ferroelectric material film may vary, depending on which type of ferroelectric material is included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), and yttrium (Y).

When the dopant is aluminum (Al), the ferroelectric material film may include 3 to 8 at % (atomic %) aluminum. Here, a ratio of the dopant may be a ratio of aluminum to the sum of hafnium and aluminum.

When the dopant is silicon (Si), the ferroelectric material film may include 2 to 10 at % silicon. When the dopant is yttrium (Y), the ferroelectric material film may include 2 to 10 at % yttrium. When the dopant is gadolinium (Gd), the ferroelectric material film may include 1 to 7 at % gadolinium. When the dopant is zirconium (Zr), the ferroelectric material film may include 50 to 80 at % zirconium.

The paraelectric material film may have the paraelectric properties. The paraelectric material film may include at least one of, for example, a silicon oxide or a metal oxide having a high dielectric constant. The metal oxide included in the paraelectric material film may include, for example, but not limited to, at least one of hafnium oxide, zirconium oxide, and aluminum oxide.

The ferroelectric material film and the paraelectric material film may include the same material. The ferroelectric material film has the ferroelectric properties, but the paraelectric material film may not have the ferroelectric properties. For example, when the ferroelectric material film and the paraelectric material film include hafnium oxide, a crystal structure of hafnium oxide included in the ferroelectric material film differs from a crystal structure of hafnium oxide included in the paraelectric material film.

The ferroelectric material film may have a thickness having the ferroelectric properties. The thickness of the ferroelectric material film may be, for example, but not limited to, 0.5 to 10 nm. Since a critical thickness that exhibits the ferroelectric properties may vary for each ferroelectric material, the thickness of the ferroelectric material film may vary depending on the ferroelectric material.

As an example, the first gate insulating film 130 may include one ferroelectric material film. As another example, the first gate insulating film 130 may include a plurality of ferroelectric material films spaced apart from each other. The first gate insulating film 130 may have a stacked film structure in which the plurality of ferroelectric material films and the plurality of paraelectric material films are alternately stacked.

The first gate spacer 140 may be disposed on the side wall of the first gate electrode 120. The first gate spacer 140 may extend in the second direction DR2.

For example, the first gate spacer 140 may not be disposed between the first sheet patterns NS1 adjacent to each other in the third direction DR3, and between the first sheet pattern NS1 and the first lower pattern BP1. The first gate spacer 140 may include only an outer spacer.

The first gate spacer 140 may include, for example, silicon nitride, silicon oxynitride, silicon oxide, silicon oxycarbonitride, silicon boron nitride, silicon oxyboron nitride, silicon oxycarbide or a combination thereof.

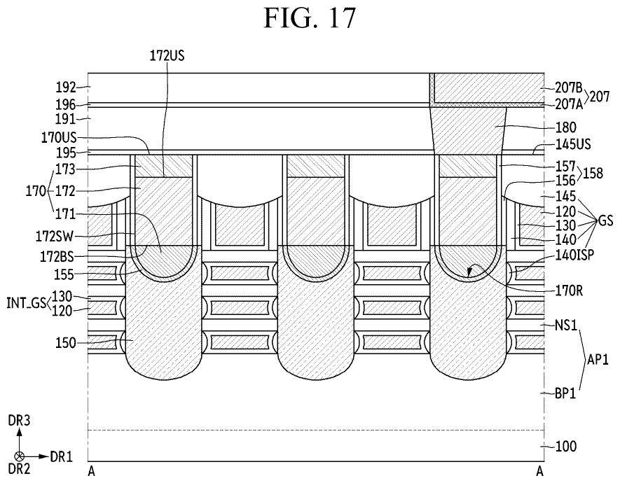

Although not shown, as an example, a cross-sectional view taken along the second active pattern AP2 in FIG. 1 may be similar to FIG. 2. As another example, a cross-sectional view taken along the second active pattern AP2 in FIG. 1 may be similar to FIG. 17 to be described below.

The gate capping pattern 145 may be disposed on the first gate electrode 120 and the first gate spacer 140. The upper surface 145US of the gate capping pattern 145 may be coplanar with an upper surface of a first interlayer insulating film 190. Unlike the shown example, the gate capping pattern 145 may be disposed between the first gate spacers 140.

The gate capping pattern 145 may include, for example, silicon nitride, silicon oxynitride, silicon oxide, silicon carbonitride, silicon oxycarbonitride or a combination thereof. The gate capping pattern 145 may include a material having an etching selectivity to a first interlayer insulating film 190.

The first source/drain pattern 150 is disposed on the substrate 100. The first source/drain pattern 150 may be disposed on the first lower pattern BP1. The first source/drain pattern 150 is in contact with the first sheet pattern NS1. For example, the first source/drain pattern 150 may be in contact with the first gate insulating film 130 of the inner gate structure INT_GS.

The first source/drain pattern 150 may be disposed between the gate structures GS. The first source/drain pattern 150 may be disposed on at least one side of the gate structure GS. The first source/drain pattern 150 is disposed on the side surface of the first gate electrode 120. For example, the first source/drain pattern 150 may be disposed on both sides of the gate structure GS. Unlike the shown example, the first source/drain pattern 150 may be disposed on one side of the gate structure GS, and may not be disposed on the other side of the gate structure GS.

The second source/drain pattern 150 is disposed on the substrate 100. The second source/drain pattern 150 may be disposed on the second lower pattern BP2. Although not shown, the shape in which the drain pattern 250 is disposed on the second lower pattern BP2 may be similar to the shape in which the first source/drain pattern 150 is disposed in FIG. 2.

As an example, the first source/drain pattern 150 may include a plurality of width expansion regions. In FIG. 2, the outer side wall of the first source/drain pattern 150 may have a wavy shape. A width of the first source/drain pattern 150 in the first direction DR1 in the width expansion region may increase and then decrease, as it goes away from the first lower pattern BP1. The width expansion region of the first source/drain pattern 150 may be defined between the first sheet patterns NS1 adjacent to each other in the third direction DR3. The width expansion region of the first source/drain pattern 150 may be defined between the first lower pattern BP1 and the first sheet pattern NS1. In the width expansion region of each of the first source/drain patterns 150, the point on which the width of the first source/drain pattern 150 is maximum is located between the first sheet pattern NS1 and the first lower pattern BP1, or between the first sheet patterns NS1 adjacent to each other in the third direction DR3.

As another example, unlike the shown example, the first source/drain pattern 150 may not include a plurality of width expansion regions.

The first source/drain pattern 150 may be included in a source/drain of a transistor that uses the first active pattern AP1, for example, the first sheet pattern NS1, as a channel region. The second source/drain pattern 250 may be included in a source/drain of a transistor that uses the second sheet pattern NS2 as a channel region.

Each of the first source/drain pattern 150 and the second source/drain pattern 250 may include an epitaxial pattern. The first source/drain pattern 150 and the second source/drain pattern 250 may include, for example, a semiconductor material.

The first source/drain pattern 150 and the second source/drain pattern 250 may include n-type impurities or p-type impurities. The n-type impurities may include at least one of phosphorus (P), arsenic (As), antimony (Sb) or bismuth (Bi). The p-type impurities may include, for example, at least one of boron (B) or gallium (Ga).

From the viewpoint of a cross-sectional view such as FIG. 2, the upper surface of the first source/drain pattern 150 is shown to be higher than the upper surface of the first active pattern AP1, but the implementation is not limited thereto.

A source/drain etching stop film 156 may be disposed on the upper surface of the field insulating film 105, the side wall of the gate structure GS, the side wall of the first source/drain pattern 150, and the second source/drain pattern 250. Although not shown, the source/drain etching stop film 156 may be disposed on the upper surface of the first source/drain pattern 150 and the upper surface of the second source/drain pattern 250.

The source/drain etching stop film 156 may include a material having an etching selectivity with respect to the first interlayer insulating film 190 to be described below. The source/drain etching stop film 156 may include, for example, silicon nitride, silicon oxynitride, silicon oxycarbonitride, silicon boron nitride, silicon oxyboron nitride, silicon oxycarbide or a combination thereof. Unlike the shown example, the source/drain etching stop film 156 may not be formed.

The first interlayer insulating film 190 may be formed on the field insulating film 105. The first interlayer insulating film 190 may be disposed on the first source/drain pattern 150 and the second source/drain pattern 250. The first interlayer insulating film 190 may not cover an upper surface 145US of the gate capping pattern.

The first interlayer insulating film 190 may include, for example, at least one of silicon oxide, silicon nitride, silicon oxynitride or a low dielectric constant material. The ow dielectric constant material may include, but not limited to, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica or combinations thereof.

A first source/drain contact 170 may be disposed on the first active pattern AP1. The first source/drain contact 170 may be disposed on the first source/drain pattern 150. The first source/drain contact 170 is connected to the first source/drain pattern 150 on the first active pattern AP1.

A second source/drain contact 270 may be disposed on the second active pattern AP2. The second source/drain contact 270 may be disposed on the second source/drain pattern 250. The second source/drain contact 270 is connected to the second source/drain pattern 250 on the second active pattern AP2.

Unlike the shown example, a part of the first source/drain contact 170 may be directly connected to the second source/drain contact 270. That is, a connecting source/drain contact simultaneously connected to the first source/drain pattern 150 and the second source/drain pattern 250 may be disposed across the first active pattern AP1 and the second active pattern AP2.

Because the description of the second source/drain contact 270 may be substantially the same as the description of the first source/drain contact 170, the following description will be provided by the use of the first source/drain contact 170.

The first source/drain contact 170 may extend in the third direction DR3 along the side wall of the first gate electrode 120. On the basis of the lowermost part of the first source/drain pattern 150, the lowermost part of the first source/drain contact 170 is lower than the upper surface of the first gate electrode 120. The lowermost part of the first source/drain contact 170 is lower than the upper surface of the first source/drain pattern 150

The first source/drain contact 170 may be disposed inside the first interlayer insulating film 190. The first source/drain contact 170 penetrates the source/drain etching stop film 156.

A first contact silicide film 155 may be disposed between the first source/drain contact 170 and the first source/drain pattern 150. The first contact silicide film 155 is disposed on the first source/drain pattern 150. The first contact silicide film 155 may define a contact recess 170R. The first source/drain contact 170 may fill the contact recess 170R.

A second contact silicide film 255 may be disposed between the second source/drain contact 270 and the second source/drain pattern 250. The description of the first contact silicide film 155 may be applied to the second contact silicide film 255. The first contact silicide film 155 and the second contact silicide film 255 may each include, for example, a metal silicide material.

A contact liner 157 may be disposed on the first source/drain pattern 150. The contact liner 157 may be disposed between the first source/drain contact 170 and the first interlayer insulating film 190.

The contact liner 157 may extend along a side wall of the first source/drain contact 170. The contact liner 157 may extend along a side wall of the gate structure GS. The contact liner 157 may be disposed between the first source/drain contact 170 and the gate structure GS. The contact liner 157 may extend to, but not limited to, the upper surface 145US of the gate capping pattern. The contact liner 157 is not formed along the bottom surface of the source/drain contact 170. In the semiconductor according to some implementations, for example, the contact liner 157 may be disposed between the first source/drain contact 170 and the source/drain etching stop film 156.

The contact liner 157 may be in contact with the first source/drain contact 170. The contact liner 157 may be in contact with the side wall of the first source/drain contact 170.

The contact liner 157 includes an insulating material. For example, the contact liner 157 may be made of an insulating material. The contact liner 157 may include, for example, silicon oxycarbide, silicon nitride, silicon oxynitride, silicon oxycarbonitride, silicon boron nitride or silicon oxyboron nitride.

As an example, the contact liner 157 may include an insulating material including carbon (C) and oxygen (O). The contact liner 157 may include, for example, silicon oxycarbide. Alternatively, the contact liner 157 may include silicon oxycarbide doped with hydrogen (H).

The contact liner 157 may extend along the side wall of the second source/drain contact 270. The source/drain etching stop film 156 and the contact liner 157 may be included in a source/drain etching liner 158.

The first source/drain contact 170 may include a lower conductive contact pattern 171, a first contact metal pattern 172, and a second contact metal pattern 173. The first contact metal pattern 172 and the second contact metal pattern 173 may be disposed on the lower conductive contact pattern 171. The first contact metal pattern 172 may be disposed between the lower conductive contact pattern 171 and the second contact metal pattern 173.

The lower conductive contact pattern 171 may be in contact with the first contact silicide film 155. For example, the lower conductive contact pattern 171 may fill at least a portion of the contact recess 170R.

In the semiconductor device according to some implementations, the lower conductive contact pattern 171 may have a single material film structure. For example, the lower conductive contact pattern 171 may be formed of a single conductive material. At this time, the lower conductive contact pattern 171 may include impurities that are unintentionally introduced in the process of forming the lower conductive contact pattern 171.

For example, the lower conductive contact pattern 171 may be formed of a first metal. The lower conductive contact pattern 171 may be a conductive pattern formed of a first metal. The first metal may include, for example, but not limited to, one of titanium (Ti), tungsten (W), molybdenum (Mo), ruthenium (Ru) or cobalt (Co). As an example, the first metal may be tungsten.

The first contact metal pattern 172 may have a single material film structure. The first contact metal pattern 172 may be formed of a second metal. The first contact metal pattern 172 may be a conductive pattern formed of a second metal. For example, the second metal may be different from the first metal included in the lower conductive contact pattern 171.

The first contact metal pattern 172 may include, for example, but not limited to, one of titanium (Ti), molybdenum (Mo), ruthenium (Ru) or cobalt (Co). As an example, the second metal may be molybdenum. The first contact metal pattern 172 may be a molybdenum contact pattern.

The first contact metal pattern 172 may include an upper surface 172US and a bottom surface 172BS that are opposite to each other in the third direction DR3. The first contact metal pattern 172 may include a side wall 172SW that connects the upper surface 172US of the first contact metal pattern and the bottom surface 172BS of the first contact metal pattern. The side wall 172SW of the first contact metal pattern may extend in the third direction DR3. The side wall 172SW of the first contact metal pattern faces the first gate electrode 120. For example, in the cross-sectional view as in FIG. 2, the side wall 172SW of the first contact metal pattern may face the first gate electrode 120 disposed on the upper surface of the first active pattern AP1.

The first contact metal pattern 172 may be in contact with the lower conductive contact pattern 171. The bottom surface 172BS of the first contact metal pattern may be in contact with the lower conductive contact pattern 171.

For example, the first contact metal pattern 172 may be in contact with the source/drain etching liner 158. The first contact metal pattern 172 may be in contact with the contact liner 157. The side wall 172SW of the first contact metal pattern may be in contact with the source/drain etching liner 158.

The second contact metal pattern 173 may have a single material film structure. The second contact metal pattern 173 may be formed of a third metal. The third metal may be different from the second metal included in the first contact metal pattern 172. The second contact metal pattern 173 may be a conductive pattern formed of the third metal.

The second contact metal pattern 173 may include, for example, tungsten (W). The third metal may be tungsten. The second contact metal pattern 173 may be a tungsten contact pattern.

The second contact metal pattern 173 may be in contact with the upper surface 172US of the first contact metal pattern. In the semiconductor device according to some implementations, the second contact metal pattern 173 may be in contact with the source/drain etching liner 158. The second contact metal pattern 173 may be in contact with the contact liner 157.

The second contact metal pattern 173 may include at least a part of the upper surface 170US of the first source/drain contact. At least a part of the upper surface 170US of the first source/drain contact may be defined by the second contact metal pattern 173. In the semiconductor device according to some implementations, the upper surface 170US of the first source/drain contact may be defined by the second contact metal pattern 173. The second contact metal pattern 173 may include the overall upper surface 170US of the first source/drain contact.

The gate contact 175 may be disposed inside the gate structure GS. The gate contact 175 may penetrate the gate capping pattern 145, and be connected to the first gate electrode 120.

The gate contact 175 may be disposed at a position that overlaps the gate structure GS. Although the gate contact 175 is shown in FIG. 1 as being disposed at a position that does not overlap the first active pattern AP1 and the second active pattern AP2, the implementation is not limited thereto. The gate contact 175 may be disposed at a position that overlaps at least one of the first active pattern AP1 and the second active pattern AP2.

The gate contact 175 may include a gate contact barrier film 176 and a gate contact filling film 177. The gate contact barrier film 176 may be disposed between the first gate electrode 120 and the gate contact filling film 177. For example, the gate contact 175 may have a multi-material film structure including different materials from each other. The contact barrier film 176 may include at least one of, for example, tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir) or rhodium (Rh). The gate contact filling film 177 may include, for example, aluminum (Al), tungsten (W), cobalt (Co), copper (Cu), ruthenium (Ru), silver (Ag), gold (Au), manganese (Mn), or molybdenum (Mo).

A second interlayer insulating film 191 may be disposed on the first interlayer insulating film 190, the gate structure GS, the first source/drain contact 170, the second source/drain contact 270, and the gate contact 175. The second interlayer insulating film 191 may include, for example, at least one of silicon oxide, silicon nitride, silicon carbonitride, silicon oxynitride, and a low dielectric constant material.

The first etching stop film 195 may be disposed between the first interlayer insulating film 190 and the second interlayer insulating film 191. The first etching stop film 195 may extend along the upper surface 145US of the gate capping pattern, the upper surface of the first interlayer insulating film 190, the upper surface of the first source/drain contact 170US, the upper surface of the second source/drain contact 270, and the upper surface of the gate contact 175US. The first etching stop film 195 is disposed on the upper surface 145US of the gate capping pattern, the upper surface of the first source/drain contact 170US, the upper surface of the second source/drain contact 270

The first etching stop film 195 may include a material having an etching selectivity with respect to the second interlayer insulating film 191. The first etching stop film 195 may include, for example, at least one of silicon nitride, silicon oxynitride, silicon oxycarbonitride, silicon boron nitride, silicon oxyboron nitride, silicon oxycarbide, aluminum oxide, aluminum nitride, aluminum oxycarbide, and combinations thereof. Although the first etching stop film 195 is shown as being a single film, the implementation is not limited thereto. Unlike the shown example, the first etching stop film 195 may not be formed.

A wiring structure is disposed on the first source/drain contact 170, the second source/drain contact 270, and the gate contact 175. The wiring structure may include a source/drain via pattern 180, a gate via pattern 185, and a wiring line 207. The source/drain via pattern 180 and the gate via pattern 185 may be disposed inside the second interlayer insulating film 191.

The source/drain via pattern 180 may be connected to the first source/drain contact 170 and the second source/drain contact 270. The source/drain via pattern 180 may penetrate the first etching stop film 195, and be in contact with the first source/drain contact 170 and the second source/drain contact 270. The source/drain via pattern 180 may be in contact with the upper surface 170US of the first source/drain contact.

The source/drain via pattern 180 may be in contact with the second contact metal pattern 173. The second contact metal pattern 173 may be disposed between the source/drain via pattern 180 and the first contact metal pattern 172.

The gate via pattern 185 may be connected to the gate contact 175. The gate via pattern 185 may penetrate the first etching stop film 195, and be in contact with the gate contact 175. The gate via pattern 185 may be in contact with the upper surface 175US of the gate contact.

The first source/drain contact 170 may be disposed between the first source/drain pattern 150 and the source/drain via pattern 180. The first source/drain contact 170 may connect the first source/drain pattern 150 and the source/drain via pattern 180. The second source/drain contact 270 may be disposed between the second source/drain pattern 250 and the source/drain via pattern 180.

The gate contact 175 may be disposed between the first gate electrode 120 and the gate via plug 185. The gate contact 175 may connect the first gate electrode 120 and the gate via plug 185.

The source/drain via pattern 180 may have a single material film structure. The source/drain via pattern 180 may include a metal capable of being selectively grown on a conductive material. The source/drain via pattern 180 may be formed of a fourth metal. The fourth metal may be different from the third metal included in the second contact metal pattern 173.

The source/drain via pattern 180 may include, but not limited to, one of titanium (Ti), molybdenum (Mo), ruthenium (Ru) or cobalt (Co). As an example, the fourth metal may be molybdenum. The source/drain via pattern 180 may be a molybdenum via pattern.

The resistivity of the molybdenum (Mo) film may vary depending on what material is present underneath.

In FIG. 5, a first experimental example (S1) is a case where molybdenum is deposited on a metal carbonitride film. For example, the metal carbonitride film of the first experimental example (S1) may include tungsten carbonitride. A second experimental example (S2) is a case where molybdenum is deposited on a metal nitride film. For example, the metal nitride film of the second experimental example (S2) may include titanium nitride. A third experimental example (S3) is a case where molybdenum is deposited on an insulating film. For example, the insulating film of the third experimental example (S3) may include silicon oxide. A fourth experimental example (S4) is a case where molybdenum is deposited on a metal film. For example, the metal film of the fourth experimental example (S4) may include tungsten.

In the first to fourth experimental examples (S1, S2, S3, and S4), as the thickness of the molybdenum film increases, the resistivity of the molybdenum film may decrease. Compared with the other experimental examples (S1, S2, and S3), the molybdenum film deposited on the tungsten film (fourth experimental example S4) has a low resistivity despite of a thin thickness. That is, when the molybdenum film of the thin thickness is formed on the tungsten film, the molybdenum film may have a low resistance despite of a thin thickness. When the molybdenum film is formed on the tungsten film, it is not necessary to increase the thickness of the molybdenum film to reduce the resistivity. Since the via pattern including the molybdenum film is formed on the source/drain contact including the tungsten film, the scaling of the semiconductor device in a vertical direction (e.g., the third direction DR3) can decrease. In addition, the performance and reliability of the semiconductor device can be improved.

The gate via pattern 185 may include a gate via barrier film 186 and a gate via filling film 187. The gate via filling film 187 is disposed on the gate via barrier film 186.

The gate via barrier film 186 may include, for example, but not limited to, at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir) or rhodium (Rh).

The gate via filling film 187 may include, for example, but not limited to, one of aluminum (Al), tungsten (W), cobalt (Co), copper (Cu), ruthenium (Ru), silver (Ag), gold (Au), manganese (Mn) or molybdenum (Mo).

A second etching stop film 196 may be disposed between the second interlayer insulating film 191 and the third interlayer insulating film 192. The second etching stop film 196 may extend along the upper surface of the second interlayer insulating film 191.

The second etching stop film 196 may include a material having an etching selectivity with respect to the third interlayer insulating film 192. The second etching stop film 196 may include, for example, at least one of silicon nitride, silicon oxynitride, silicon oxycarbonitride, silicon boron nitride, silicon oxyboron nitride, silicon oxycarbide, aluminum oxide, aluminum nitride, aluminum oxycarbide, and combinations thereof. The second etching stop film 196 is shown as being a single film, but the implementation is not limited thereto. Unlike the shown example, the second etching stop film 196 may not be formed.

The wiring line 207 may be disposed inside the third interlayer insulating film 192. The wiring line 207 is connected to the source/drain via pattern 180. The wiring line 207 is in contact with the source/drain via pattern 180. The wiring line 207 is connected to the gate via pattern 185. The wiring line 207 is in contact with the gate via pattern 185.

The wiring line 207 may include a wiring barrier film 207A and a wiring filling film 207B. The wiring barrier film 207A may include at least one of, for example, tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh) or a two-dimensional material (2D material). The wiring filling film 207B may include at least one of, for example, aluminum (Al), copper (Cu), tungsten (W), cobalt (Co), ruthenium (Ru), silver (Ag), gold (Au), manganese (Mn), or molybdenum (Mo).

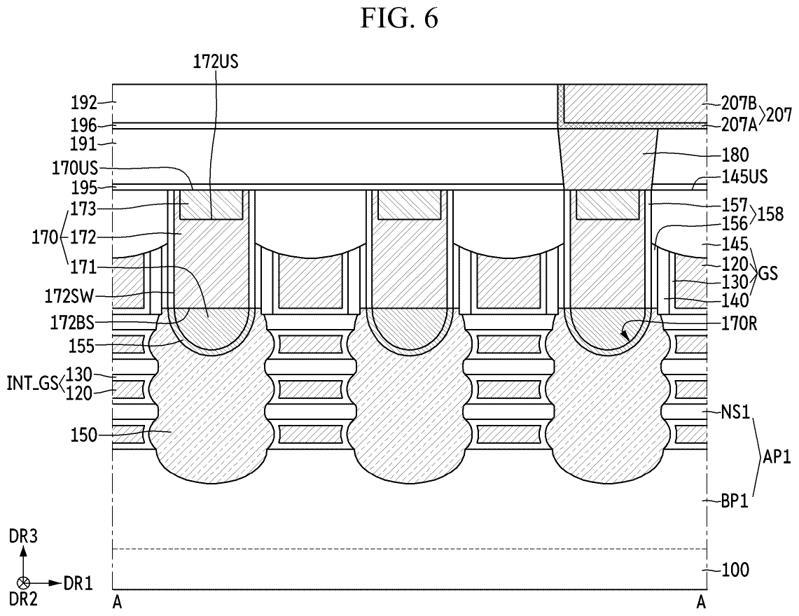

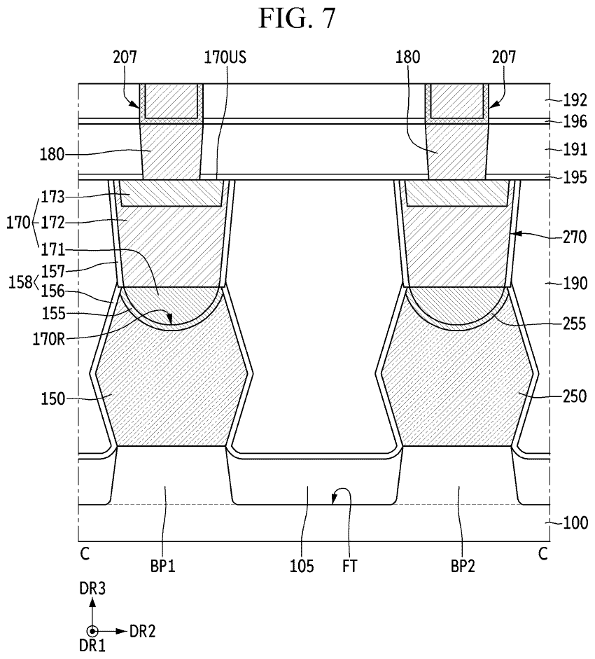

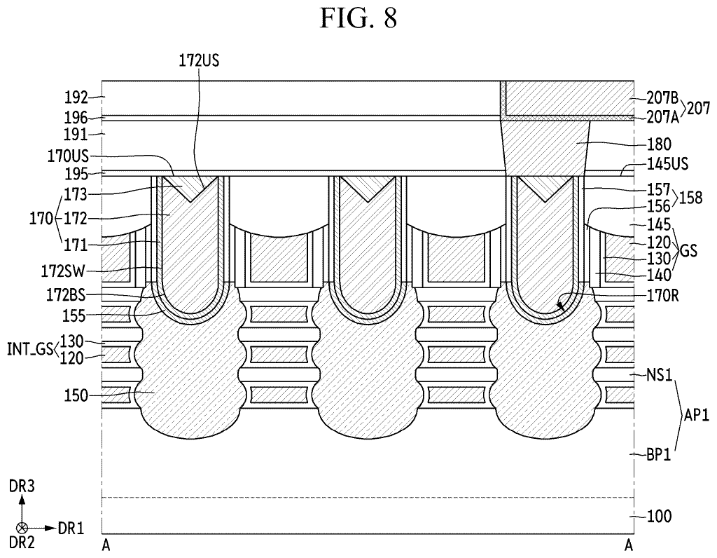

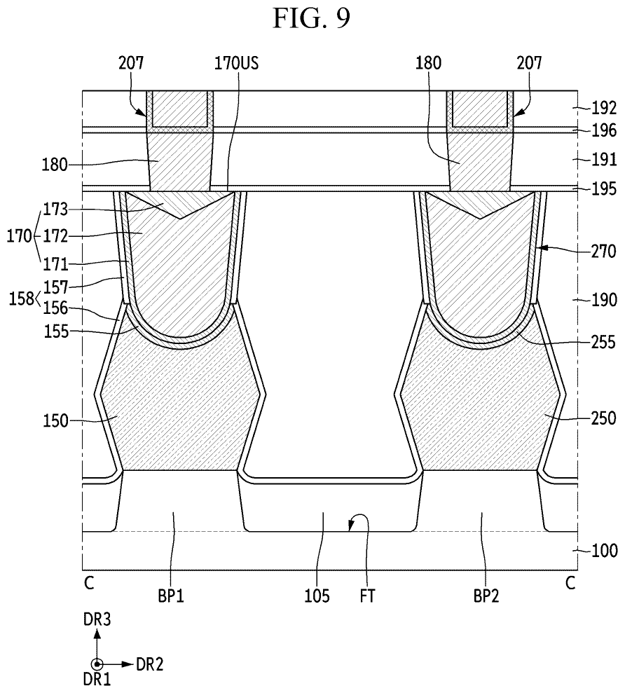

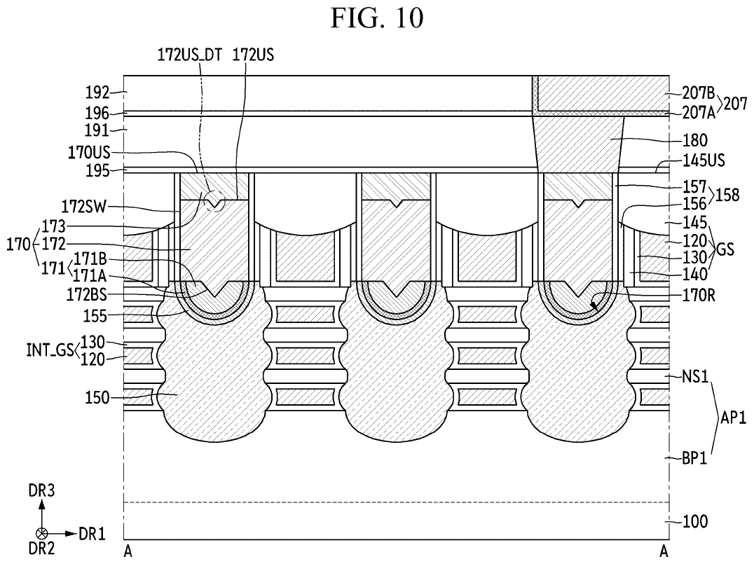

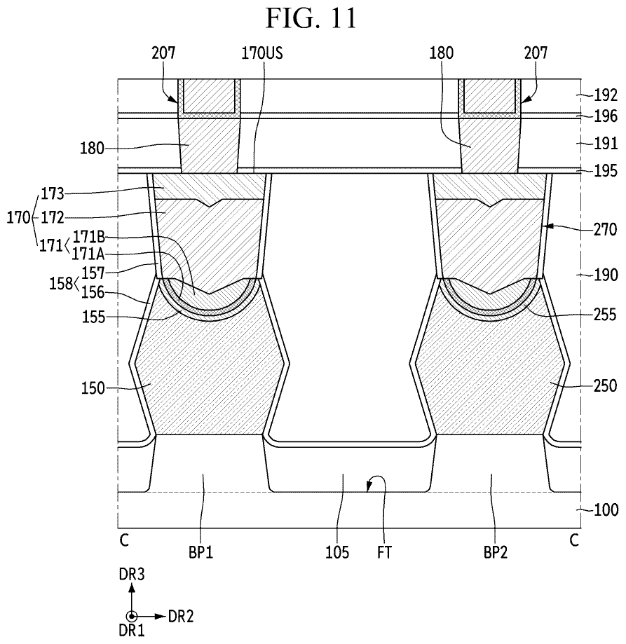

FIGS. 6 and 7 are diagrams for explaining a semiconductor device according to some implementations. FIGS. 8 and 9 are diagrams for explaining the semiconductor device according to some implementations. FIGS. 10 and 11 are diagrams for explaining the semiconductor device according to some implementations. For convenience of explanation, the following description will focus on differences from those described using FIGS. 1 to 5.

Referring to FIGS. 6 and 7, in the semiconductor device according to some implementations, a part of the first contact metal pattern 172 may extend along a boundary between the second contact metal pattern 173 and the contact liner 157.

The first contact metal pattern 172 may cover the side wall of the second contact metal pattern 173. The upper surface 172US of the first contact metal pattern may have a bowl shape.

Because a part of the first contact metal pattern 172 is interposed between the second contact metal pattern 173 and the contact liner 157, the second contact metal pattern 173 may not be in contact with the contact liner 157.

The upper surface 170US of the first source/drain contact may be defined by the first contact metal pattern 172 and the second contact metal pattern 173. The second contact metal pattern 173 may define a part of the upper surface 170US of the first source/drain contact.

Referring to FIGS. 8 and 9, in the semiconductor device according to some implementations, the first contact metal pattern 172 does not be in contact with the source/drain etch liner 158.

The first contact metal pattern 172 does not be in contact with the contact liner 157. The lower conductive contact pattern 171 may extend along the boundary between the first contact metal pattern 172 and the contact liner 157.

The lower conductive contact pattern 171 may extend along the profile of the contact recess 170R. The lower conductive contact pattern 171 may extend along the side wall 172SW of the first contact metal pattern. The lower conductive contact pattern 171 may be in contact with the side wall 172SW of the first contact metal pattern. The first contact metal pattern 172 may include an interface that forms a boundary with the lower conductive contact pattern 171. In the portion in which the first contact metal pattern 172 and the first source/drain pattern 150 overlap in the first and second directions DR1 and DR2, the interface of the first contact metal pattern 172 may be the bottom surface 172BS of the first contact metal pattern.

The lower conductive contact pattern 171 may extend along the boundary between the second contact metal pattern 173 and the contact liner 157. The second contact metal pattern 173 may be in contact with the lower conductive contact pattern 171. The second contact metal pattern 173 may have a triangular shape from the viewpoint of a cross-sectional view, but the implementation is not limited thereto.

The lower conductive contact pattern 171 may include at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir) or rhodium (Rh).

Referring to FIGS. 10 and 11, in the semiconductor device according to some implementations, the lower conductive contact pattern 171 may include a first lower conductive contact liner 171A and a second lower conductive contact liner 171B that are sequentially formed on the first contact silicide film 155.

The second lower conductive contact liner 171B may be disposed between the first lower conductive contact liner 171A and the first contact metal pattern 172. The first lower conductive contact liner 171A may extend along the profile of the contact recess 170R. The first lower conductive contact liner 171A may be in contact with the first contact silicide film 155. The first lower conductive contact liner 171A may be in contact with the first contact metal pattern 172.

The second lower conductive contact liner 171B may be in contact with the first lower conductive contact liner 171A. The second lower conductive contact liner 171B may be in contact with the first contact metal pattern 172.

The first lower conductive contact liner 171A, for example, the lower conductive contact pattern 171, may include at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir) or rhodium (Rh).

The second lower conductive contact liner 171B may be formed of a fifth metal. As an example, the fifth metal may be different from the second metal included in the first contact metal pattern 172.

As another example, the fifth metal may be the same as the second metal included in the first contact metal pattern 172. A method of forming the second lower conductive contact liner 171B may be different from a method of forming the first contact metal pattern 172. Even if the second lower conductive contact liner 171B and the first contact metal pattern 172 include the same metal, the boundary between the second lower conductive contact liner 171B and the first contact metal pattern 172 may be distinguished.

The fifth metal may include, for example, one of tungsten (W) or molybdenum (Mo).

The upper surface 172US of the first contact metal pattern may include a dent region 172US_DT that is recessed toward the first source/drain pattern 150.

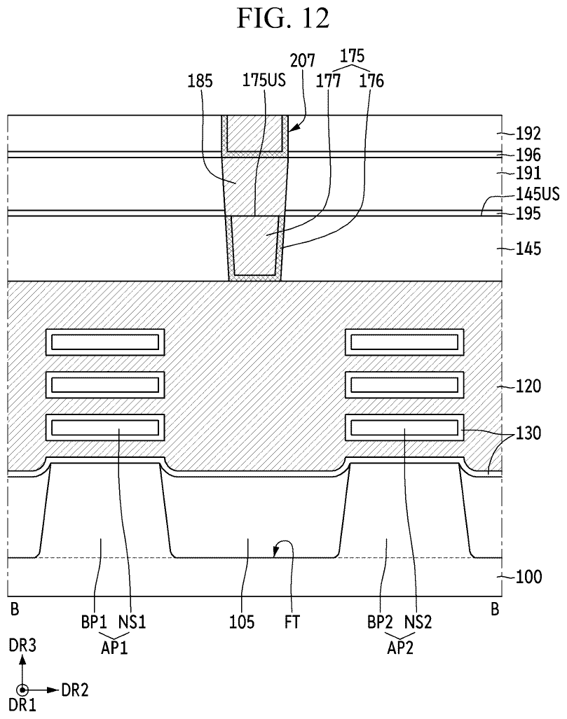

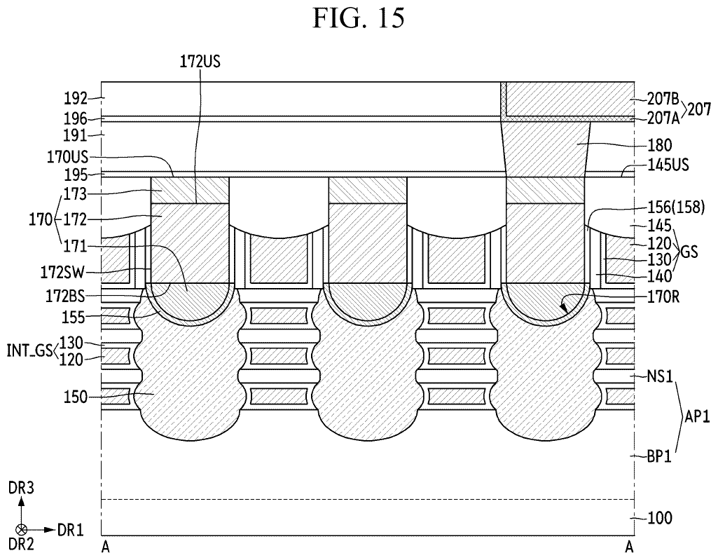

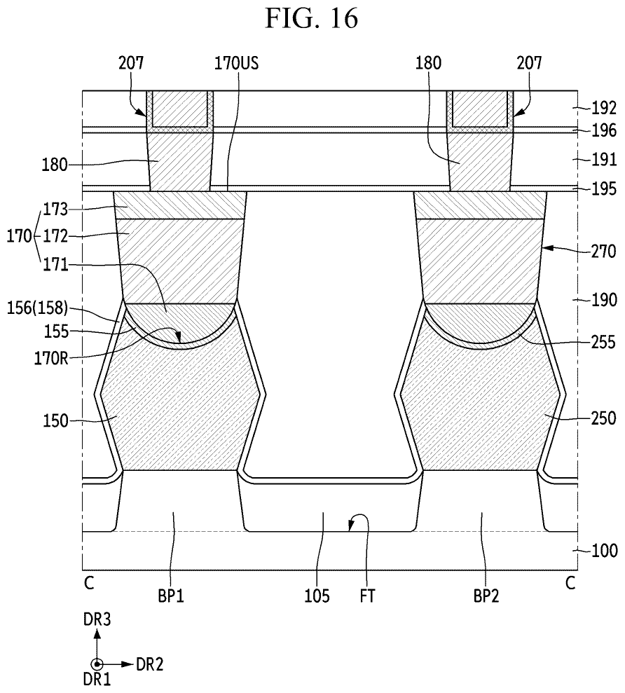

FIGS. 12 to 14 are diagrams for explaining a semiconductor device according to some implementations. FIGS. 15 and 16 are diagrams for explaining a semiconductor device according to some implementations. FIG. 17 is a diagram for explaining the semiconductor device according to some implementations. For convenience of explanation, differences from those described using FIGS. 1 to 5 will be mainly described.

Referring to FIG. 12, in the semiconductor device according to some implementations, a gate via pattern 185 may have a single material film structure.

The gate via pattern 185 may include a metal capable of being selectively grown on a conductive material. The gate via pattern 185 may include, but not limited to, one of titanium (Ti), molybdenum (Mo), ruthenium (Ru), or cobalt (Co).

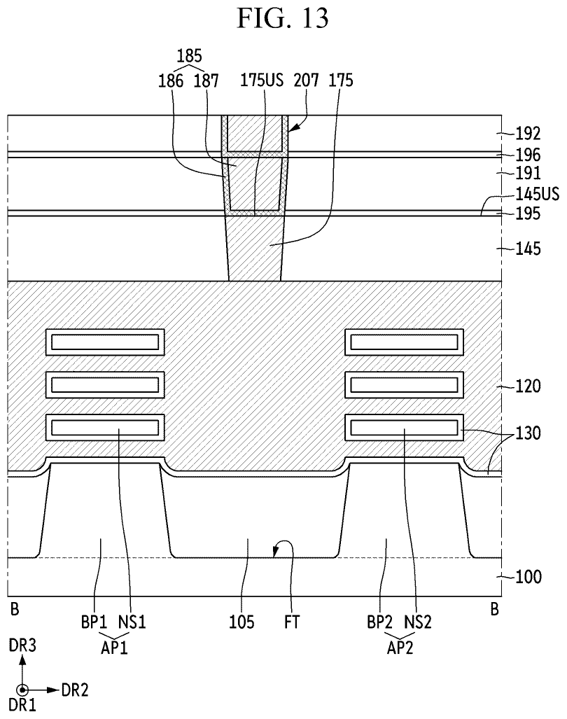

Referring to FIG. 13, in the semiconductor device according to some implementations, the gate contact 175 may have a single material film structure.

The gate contact 175 may include a metal capable of being selectively grown on a conductive material. The gate contact 175 may include, but not limited to, one of titanium (Ti), molybdenum (Mo), ruthenium (Ru), or cobalt (Co).

In FIGS. 12 and 13, unlike those shown, the gate contact 175 and the gate via pattern 185 may each have a single material film structure.

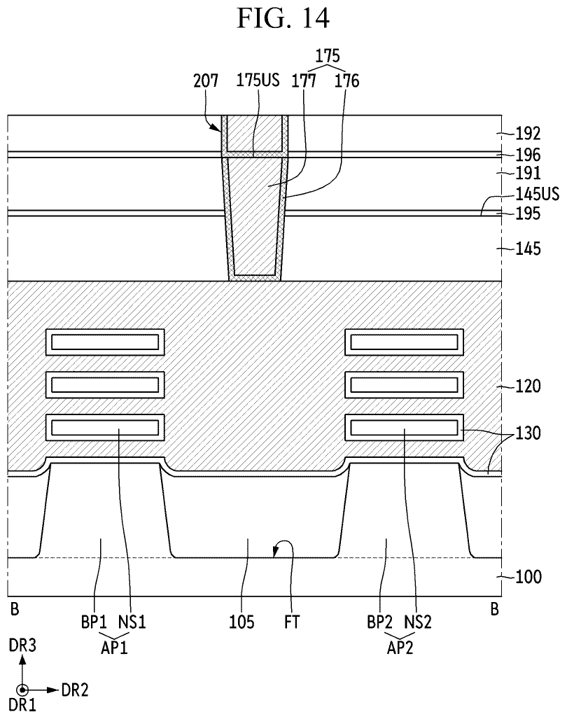

Referring to FIG. 14, in the semiconductor device according to some implementations, the gate contact 175 may penetrate the first etching stop film 195 and the gate capping pattern 145.

The gate contact 175 may be disposed inside the gate capping pattern 145 and the second interlayer insulating film 191. The upper surface 175US of the gate contact is higher than the upper surface 145US of the gate capping pattern. A part of the gate contact 175 protrudes beyond the upper surface 145US of the gate capping pattern.

The gate contact 175 may be connected to the wiring line 207 without a gate via pattern (185 of FIG. 3).

Referring to FIGS. 15 and 16, in the semiconductor device according to some implementations, the source/drain etching liner 158 may not include a contact liner (157 of FIG. 2).

The first contact metal pattern 172 may be in contact with the source/drain etching stop film 156. For example, the side wall 172SW of the first contact metal pattern may be in contact with the source/drain etching stop film 156. When the source/drain etching stop film 156 is not formed, the side wall 172SW of the first contact metal pattern may be in contact with the gate structure GS.

The second contact metal pattern 173 may be in contact with the gate capping pattern 145.

Referring to FIG. 17, in the semiconductor device according to some implementations, the gate structure GS may further include a plurality of inner spacers 140ISP disposed between the first sheet patterns NS1 adjacent to each other in the third direction DR3.

The inner spacers 140ISP are disposed between the inner gate structure INT_GS and the first source/drain pattern 150. Since the inner spacers 140ISP are disposed, the inner gate structure INT_GS does not be in contact with the first source/drain pattern 150.

The inner spacers 140ISP may include, for example, silicon nitride, silicon oxynitride, silicon oxide, silicon oxycarbonitride, silicon boron nitride, silicon oxyboron nitride, silicon oxycarbide or combinations thereof.

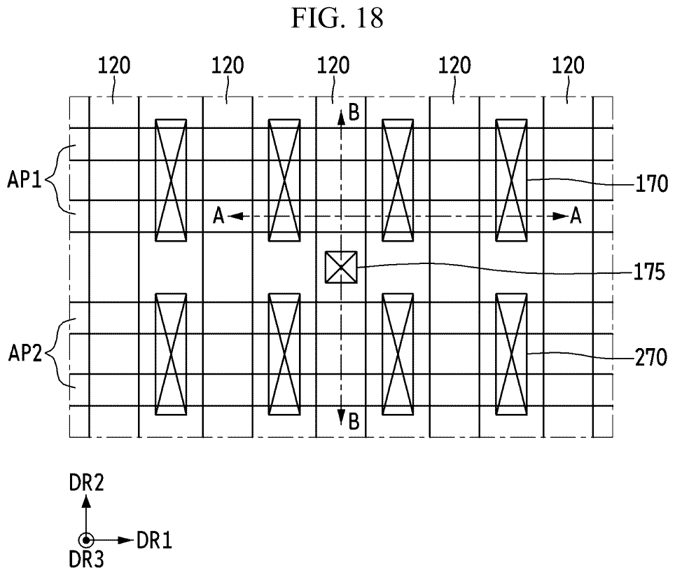

FIGS. 18 to 21 are diagrams for explaining a semiconductor device according to some implementations. For convenience of explanation, differences from those explained using FIGS. 1 to 5 will be mainly described.

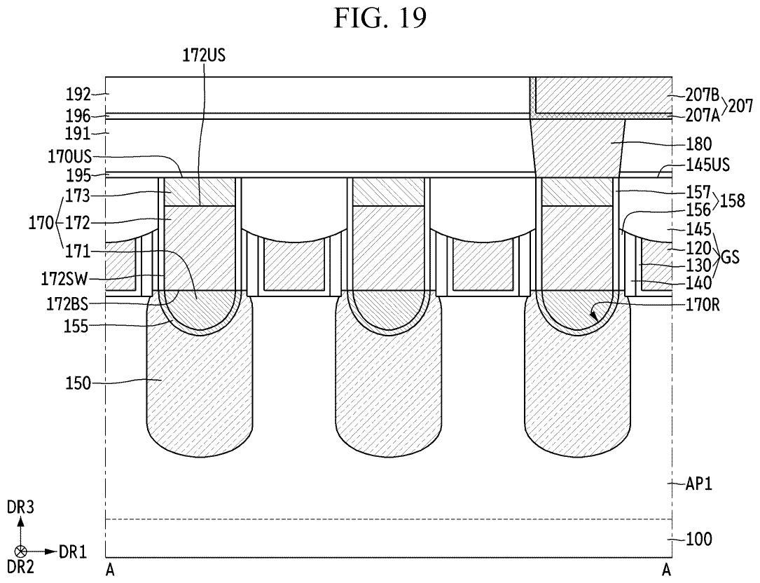

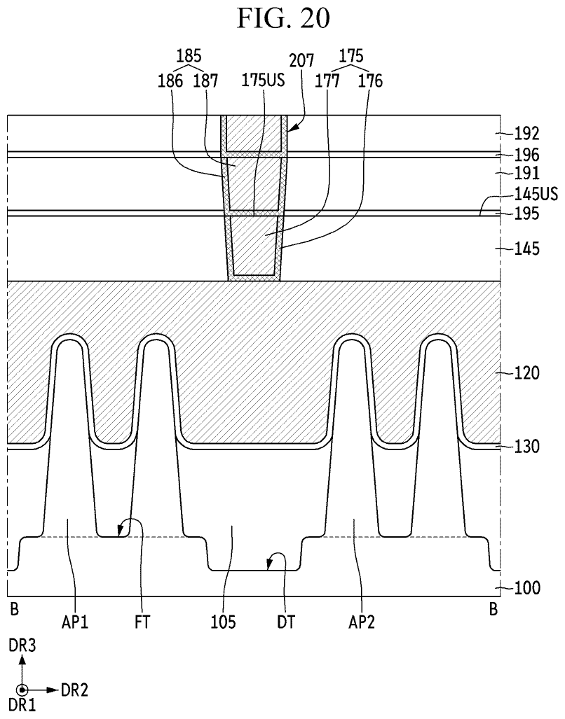

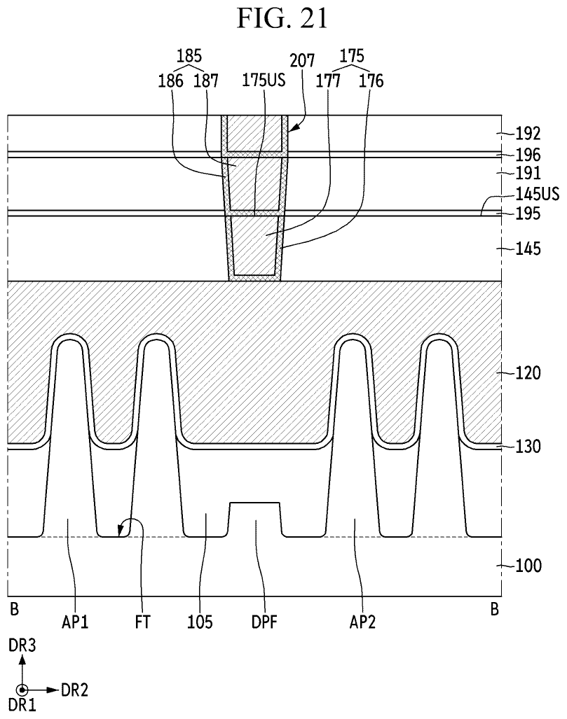

For reference, FIG. 18 is an example layout diagram for explaining a semiconductor device according to some implementations. FIG. 19 is a cross-sectional view taken along A-A of FIG. 18. FIGS. 20 and 21 are cross-sectional views taken along B-B of FIG. 18, respectively.

Referring to FIGS. 18 to 21, in the semiconductor device according to some implementations, each of the first active pattern AP1 and the second active pattern AP2 may be fin-type patterns that protrude above the upper surface of the field insulating film 105.

In FIG. 20, the first active pattern AP1 and the second active pattern AP2 may each be disposed in an active region defined by a deep trench DT. The deep trench DT may define a field region disposed between the active regions.

Although each of two first active patterns AP1 and two second active patterns AP2 is shown as being disposed in the active region, the implementation is not limited thereto. The number of first active patterns AP1 and second active patterns AP2 disposed in the active region may be one or more than three. The first active pattern AP1 disposed in the active region and the second active pattern AP2 disposed in the active region may be separated by the fin trench FT extending long in the first direction DR1, respectively.

The field insulating film 105 may fill the deep trench DT.

In FIG. 21, a dummy protruding pattern DPF may be disposed in the field region that distinguishes the active region. The deep trench (DT of FIG. 20) is not formed in the field region. The upper surface of the dummy protruding pattern DPF is covered with the field insulating film 105.

The first active pattern AP1 and the second active pattern AP2 may each include, for example, silicon or germanium, which are elemental semiconductor materials. In addition, the first active pattern AP1 and the second active pattern AP2 may include a compound semiconductor, and may include, for example, a group IV-IV compound semiconductor or a group III-V compound semiconductor. As an example, the first active pattern AP1 and the second active pattern AP2 may include the same material. As another example, the first active pattern AP1 may include a material different from that of the second active pattern AP2.

When the first active pattern AP1 is disposed in the PMOS formation region and the second active pattern AP2 is disposed in the NMOS formation region, the first active pattern AP1 is a fin-type pattern including silicon-germanium, and the second active pattern AP2 may be a fin-type pattern including silicon, but the implementation is not limited thereto.

The gate structure GS does not include an inner gate structure (INT_GS of FIG. 2).

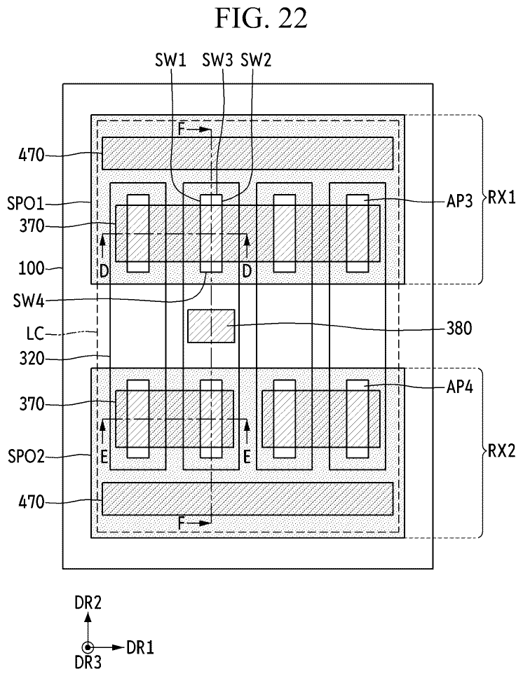

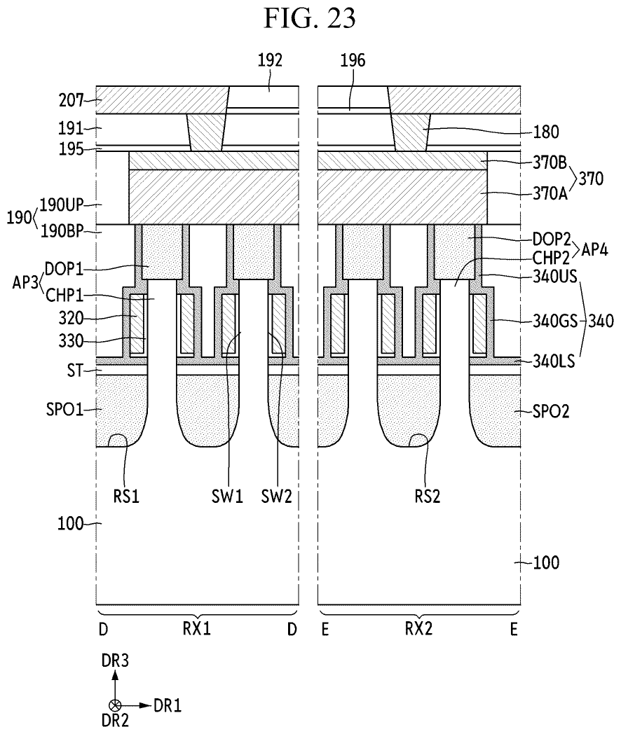

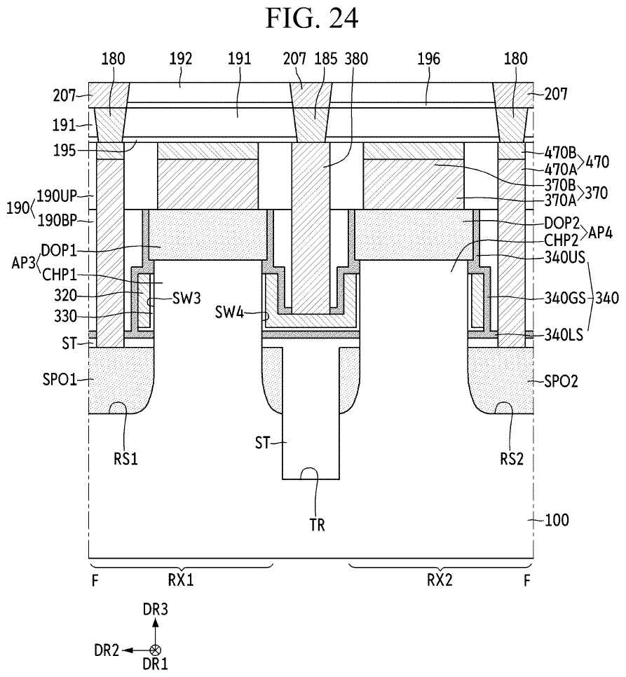

FIGS. 22 to 24 are diagrams for explaining a semiconductor device according to some implementations. For reference, FIG. 22 is a plan view for explaining a semiconductor device according to some implementations. FIG. 23 is a cross-sectional view taken along lines D-D and E-E of FIG. 22. FIG. 24 is a cross-sectional view taken along line F-F of FIG. 22.

Referring to FIGS. 22 to 24, a logic cell LC may be provided on the substrate 100. The logic cell LC may mean a logic element (e.g., an inverter, a flip-flop, etc.) that performs a specific function. The logic cell LC may include vertical transistors (Vertical FET) that constitute the logic element, and wirings that connect the vertical transistors to each other.

The logic cell LC on the substrate 100 may include a first active region RX1 and a second active region RX2. For example, the first active region RX1 may be a PMOSFET region, and the second active region RX2 may be an NMOSFET region. The first and second active regions RX1 and RX2 may be defined by a trench TR formed in the upper part of the substrate 100. The first and second active regions RX1 and RX2 may be spaced apart from each other in the second direction DR2.

A first lower epitaxial pattern SPO1 may be provided on the first active region RX1, and a second lower epitaxial pattern SPO2 may be provided on the second active region RX2. From a planar view point, the first lower epitaxial pattern SPO1 may overlap the first active region RX1, and the second lower epitaxial pattern SPO2 may overlap the second active region RX2. The first and second lower epitaxial patterns SPO1 and SPO2 may be epitaxial patterns formed by a selective epitaxial growth process. The first lower epitaxial pattern SPO1 may be provided in a first recess region RS1 of the substrate 100, and the second lower epitaxial pattern SPO2 may be provided in a second recess region RS2 of the substrate 100.

Third active patterns AP3 may be provided on the first active region RX1, and fourth active patterns AP4 may be provided on the second active region RX2. Each of the third and fourth active patterns AP3 and AP4 may have the form of a vertically protruding fin. From a planar view point, each of the third and fourth active patterns AP3 and AP4 may have the form of a bar extending in the second direction DR2. The third active patterns AP3 may be arranged along the first direction DR1, and the fourth active patterns AP4 may be arranged along the first direction DR1.

Each of the third active patterns AP3 may include a first channel pattern CHP1 protruding vertically from a first lower epi pattern SPO1, and a first upper epi pattern DOP1 on the first channel pattern CHP1. Each of the fourth active patterns AP4 may include a second channel pattern CHP2 protruding vertically from a second lower epi pattern SPO2, and a second upper epi pattern DOP2 on the second channel pattern CHP2.

An element separation film ST may be provided on the substrate 100 to fill the trench TR. The element separation film ST may cover the upper surfaces of the first and second lower epi patterns SPO1 and SPO2. The third and fourth active patterns AP3 and AP4 may protrude vertically from the element separation film ST.

A plurality of second gate electrodes 320 extending parallel to each other in the second direction DR2 may be provided on the element separation film ST. The second gate electrodes 320 may be arranged along the first direction DR1. The second gate electrodes 320 may surround the first channel pattern CHP1 of the third active pattern AP3, and may surround the second channel pattern CHP2 of the fourth active pattern AP4. For example, the first channel pattern CHP1 of the third active pattern AP3 may have first to fourth side walls SW1 to SW4. The first and second side walls SW1 and SW2 may be opposite to each other in the first direction DR1, and the third and fourth side walls SW3 and SW4 may be opposite to each other in the second direction DR2. The second gate electrode 320 may be provided on the first to fourth side walls SW1 to SW4. In other words, the second gate electrode 320 may surround the first to fourth side walls SW1 to SW4.

A second gate insulating film 330 may be interposed between the second gate electrode 320 and each of the first and second channel patterns CHP1 and CHP2. The second gate insulating film 330 may cover the bottom surface of the second gate electrode 320 and the inner side wall of the second gate electrode 320. For example, the second gate insulating film 330 may directly cover the first to fourth side walls SW1 to SW4 of the third active pattern AP3.

The first and second upper epi patterns DOP1 and DOP2 may protrude vertically above the second gate electrode 320. The upper surface of the second gate electrode 320 may be lower than the bottom surfaces of each of the first and second upper epi patterns DOP1 and DOP2. In other words, each of the third and fourth active patterns AP3 and AP4 may have a structure that protrudes vertically from the substrate 100 and penetrates the second gate electrode 320.

The semiconductor device according to some implementations may include vertical transistors in which carriers move in the third direction DR3. For example, when a voltage is applied to the second gate electrode 320 to turn the transistor “on,” the carriers may move from the lower epi patterns SPO1 and SPO2 to the upper epi patterns DOP1 and DOP2 through the channel patterns CHP1 and CHP2. In the semiconductor device according to some implementations, the second gate electrode 320 may completely surround the side walls SW1 to SW4 of the channel patterns CHP1 and CHP2. The transistor according to the present disclosure may be a three-dimensional field effect transistor (e.g., VFET) having a gate-all-around structure. Because the gate surrounds the channel, the semiconductor device according to some implementations may have excellent electrical characteristics.

A spacer 340 that covers the second gate electrodes 320 and the third and fourth active patterns AP3 and AP4 may be provided on the element separation film ST. The spacer 340 may include silicon nitride or silicon oxynitride. The spacer 340 may include a lower spacer 340LS, an upper spacer 340US, and a second gate spacer 340GS between the lower and upper spacers 340LS and 340US.

The lower spacer 340LS may directly cover the upper surface of the element separation film ST. The second gate electrodes 320 may be spaced apart from the element separation film ST in the third direction DR3 by the lower spacer 340LS. The second gate spacer 340GS may cover the upper surface and outer side wall of each of the second gate electrodes 320. The upper spacer 340 may cover the first and second upper epi patterns DOP1 and DOP2. However, the upper spacer 340US may not cover the upper surfaces of the first and second upper epi patterns DOP1 and DOP2, and may expose the upper surfaces of the first and second upper epi patterns DOP1 and DOP2.

A first lower interlayer insulating film 190BP may be provided on the spacer 340. The upper surface of the first lower interlayer insulating film 190BP may be substantially coplanar with the upper surfaces of the first and second upper epi patterns DOP1 and DOP2. A first upper interlayer insulating film 190UP, a first etching stop film 195, a second interlayer insulating film 191, a second etching stop film 196, and a third interlayer insulating film 192 may be sequentially stacked on the first lower interlayer insulating film 190BP. The first lower interlayer insulating film 190BP and the first upper interlayer insulating film 190UP may be included in the first interlayer insulating film 190. The first upper interlayer insulating film 190UP may cover the upper surfaces of the first and second upper epi patterns DOP1 and DOP2.

At least one first vertical source/drain contact 370 which penetrates the first upper interlayer insulating film 190UP and is connected to the first and second upper epi patterns DOP1 and DOP2 may be provided. At least one second vertical source/drain contact 470, which penetrates the first interlayer insulating film 190, the lower spacer 340LS, and the device element separation film ST and is connected to the first and second lower epi patterns SPO1 and SPO2, may be provided. A vertical gate contact 380, which penetrates the first upper interlayer insulating film 190UP, the first lower interlayer insulating film 190BP, and the second gate spacer 340GS and is connected to the second gate electrode 320, may be provided.

The first etching stop film 195, the second interlayer insulating film 191, and the second etching stop film 196 may be disposed between the first upper interlayer insulating film 190UP and the third interlayer insulating film 192.

A source/drain via pattern 180 and a gate via pattern 185 may be provided inside the first etching stop film 195 and the second interlayer insulating film 191. A wiring line 207 may be provided inside the third interlayer insulating film 192 and the second etching stop film 196. Although the vertical gate contact 380, the gate via pattern 185, and the wiring line 207 are shown as being single films, this is only for convenience of explanation, and the implementations are not limited thereto.

The first vertical source/drain contact 370 may include a first vertical lower contact metal pattern 370A and a first vertical upper contact metal pattern 370B. The second vertical source/drain contact 470 may include a second vertical lower contact metal pattern 470A and a second vertical upper contact metal pattern 470B.

The contents of the first contact metal pattern 172 described in FIGS. 1 to 21 may be applied to each of the first vertical lower contact metal pattern 370A and the second vertical source/drain contact 470. The first vertical upper contact metal pattern 370B and the second vertical upper contact metal pattern 470B may be formed of tungsten. The first vertical upper contact metal pattern 370B and the second vertical upper contact metal pattern 470B may be tungsten contact patterns.

The first vertical source/drain contact 370 and the second vertical source/drain contact 470 are shown as not including a lower conductive contact pattern (e.g., 171 of FIG. 2), but the implementations are not limited thereto.

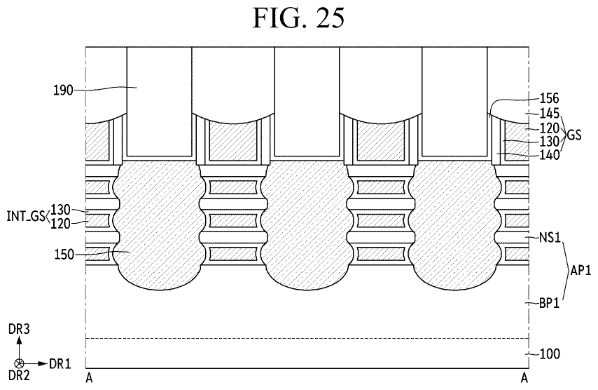

FIGS. 25 to 31 are intermediate stage diagrams for explaining a method for fabricating a semiconductor device according to some implementations.

Referring to FIG. 25, the first source/drain pattern 150 may be formed on the first active pattern AP1.

The source/drain etching stop film 156 and the first interlayer insulating film 190 are sequentially formed on the first source/drain pattern 150.

After forming the first interlayer insulating film 190, a gate structure GS may be formed through a replacement metal gate (RMG) process. During the formation of the gate capping pattern 145, a part of the source/drain etching stop film 156 may be etched. Thus, the gate capping pattern 145 may be formed on the source/drain etching stop film 156, but the implementation is not limited thereto.

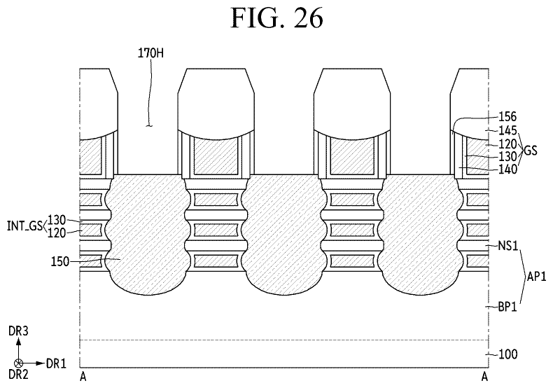

Referring to FIGS. 25 and 26, a contact hole 170H may be formed in the first interlayer insulating film 190.

The contact hole 170H may expose the first source/drain pattern 150. While the contact hole 170H is formed, a part of the source/drain etching stop film 156 may be removed. A bottom surface of the contact hole 170H may be defined by the first source/drain pattern 150.

Unlike the shown example, while the contact hole 170H is being formed, the source/drain etching stop film 156 may not be removed. In such a case, the bottom surface of the contact hole 170H may be defined by the source/drain etching stop film 156.

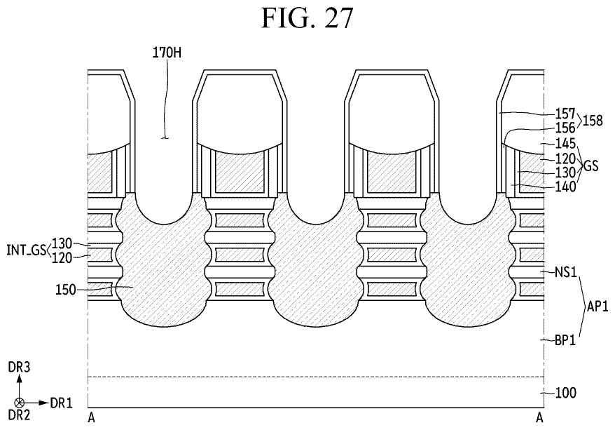

Referring to FIGS. 26 and 27, the contact liner 157 may be formed along the side wall of the contact hole 170H and the upper surface of the gate capping pattern 145.

More specifically, a pre-contact liner film may be formed along the side wall and bottom surface of the contact hole 170H. The pre-contact liner film may be formed along the upper surface of the gate capping pattern 145 and the upper surface of the first source/drain pattern 150. The pre-contact liner film may be formed using, for example, but not limited to, a chemical vapor deposition (CVD) method. The thickness of the pre-contact liner film may not be uniform. For example, the thickness of the pre-contact liner film on the upper surface of the first source/drain pattern 150 may be smaller than the thickness of the pre-contact liner film on the upper surface of the gate capping pattern 145, but the implementation is not limited thereto.

The pre-contact liner film on the bottom surface of the contact hole 170H may be removed, using the directional etching. The contact liner 157 may be formed, accordingly. While the pre-contact liner film on the bottom surface of the contact hole 170H is being removed, the pre-contact liner film on the upper surface of the gate capping pattern 145 may not be completely removed, but the implementation is not limited thereto. When the pre-contact liner film on the upper surface of the gate capping pattern 145 is completely removed, the contact liner 157 is not formed on the upper surface of the gate capping pattern 145.

When the source/drain etching stop film 156 on the upper surface of the first source/drain pattern 150 is not removed before the pre-contact liner film is formed, the source/drain etching stop film 156 on the upper surface of the first source/drain pattern 150 may be removed during the formation of the contact liner 157.

Next, a part of the first source/drain pattern 150 may be removed, using the contact liner 157 as a mask.

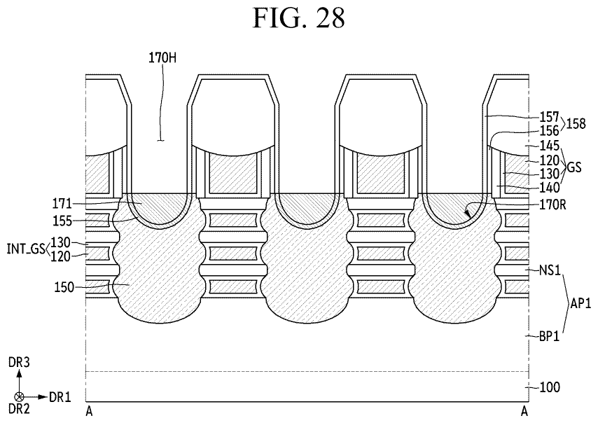

Referring to FIG. 28, the first contact silicide film 155 may be formed on the first source/drain pattern 150.

The first contact silicide film 155 may be formed, using a silicide process. The first contact silicide film 155 may define a contact recess 170R.

Next, a lower conductive contact pattern 171 may be formed on the first contact silicide film 155. The lower conductive contact pattern 171 may be formed in the contact hole 170H. The lower conductive contact pattern 171 may fill at least a part of the contact recess 170R. More specifically, a pre-lower conductive contact film may be formed in the contact hole 170H. The pre-lower conductive contact film may fill the contact hole 170H. A part of the pre-lower conductive contact film may be etched to form the lower conductive contact pattern 171.

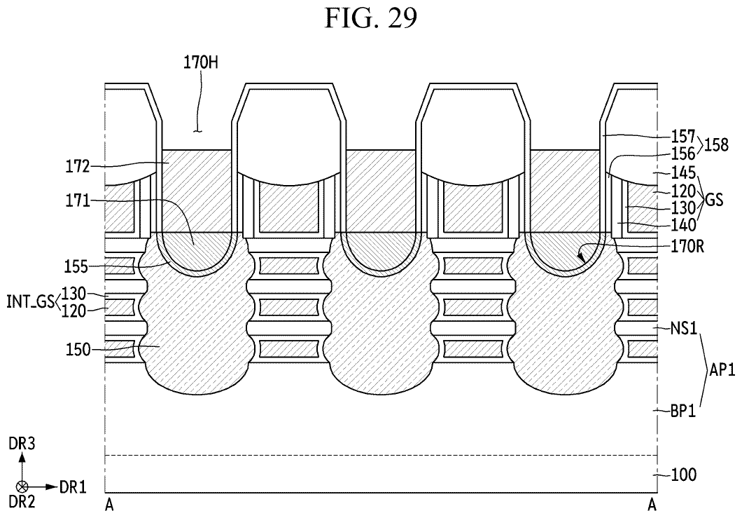

Referring to FIG. 29, the first contact metal pattern 172 may be formed on the lower conductive contact pattern 171.

The first contact metal pattern 172 may be formed inside the contact hole 170H. For example, the first contact metal pattern 172 may be formed using, for example, but not limited to, a chemical vapor deposition (CVD) method. The chemical vapor deposition method may include a selective chemical vapor deposition method.

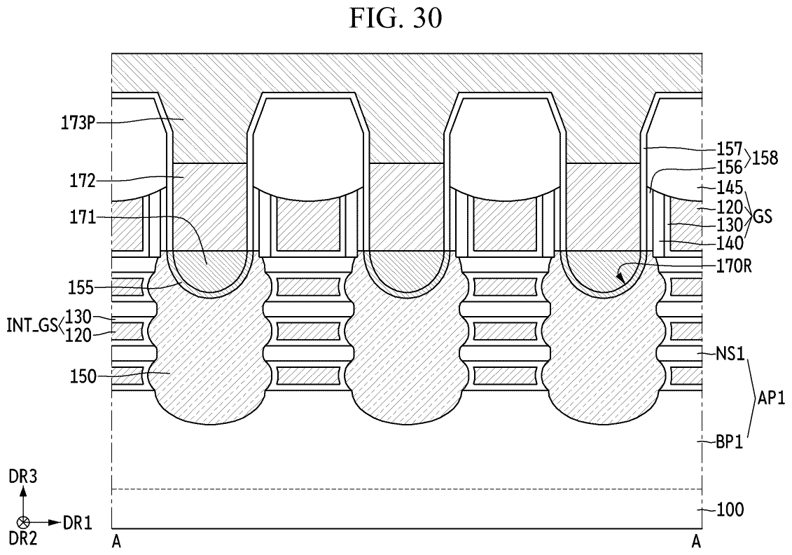

Referring to FIG. 30, a pre-contact metal pattern 173P may be formed on the first contact metal pattern 172.

The pre-contact metal pattern 173P may fill the remainder of the contact hole 170H. The pre-contact metal pattern 173P may be formed on the upper surface of the gate capping pattern 145. The pre-contact metal pattern 173P may be formed using, but not limited to, a chemical vapor deposition (CVD) or a physical vapor deposition (PVD).

Unlike the shown example, before forming the pre-contact metal pattern 173P, a seed metal liner may be formed along the upper surface of the first contact metal pattern 172, the upper surface of the gate capping pattern 145, and the side wall of the contact hole 170H. For example, the seed metal liner may include the metal included in the first contact metal pattern 172.

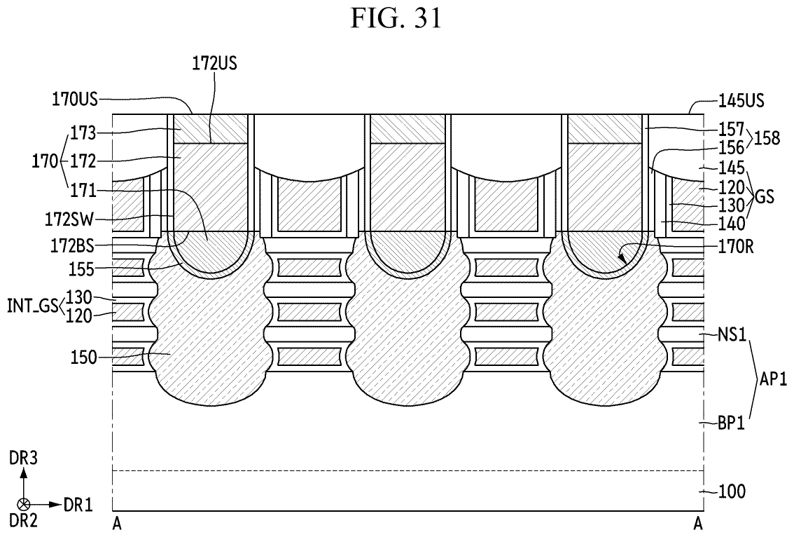

Referring to FIGS. 30 and 31, the pre-contact metal pattern 173P on the upper surface of the gate capping pattern 145 may be removed to form the second contact metal pattern 173.

Accordingly, the first source/drain contact 170 may be formed. The upper surface 170US of the first source/drain contact may be coplanar with the upper surface 145US of the gate capping pattern.

While the second contact metal pattern 173 is being formed, a part of the gate capping pattern 145 may also be removed. The thickness of the gate capping pattern 145 may decrease.

Next, referring to FIGS. 2 and 3, the source/drain via pattern 180 and the wiring line 207 may be formed. As an example, the gate contact 175 may be formed before the first etching stop film 195 is formed. As another example, the gate contact 175 may be formed after the first etching stop film 195 and the second interlayer insulating layer 191 are formed.

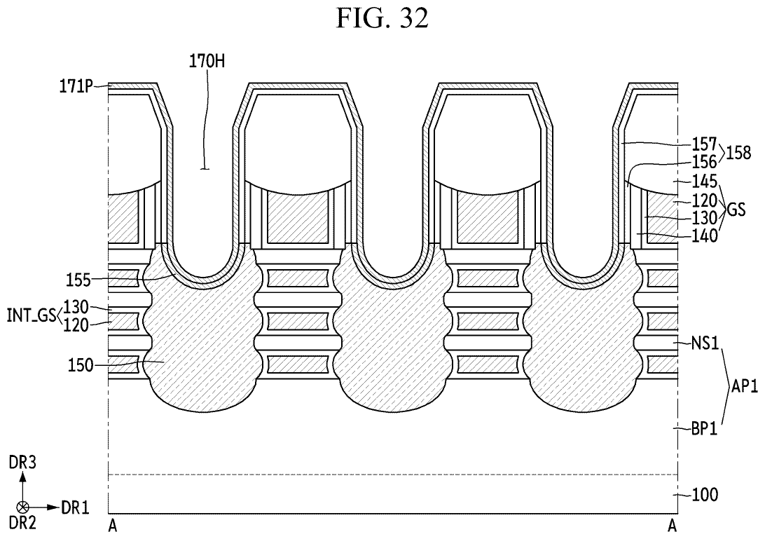

FIGS. 32 to 35 are intermediate stage diagrams for explaining a method for fabricating a semiconductor device according to some implementations. FIG. 32 may be a fabricating process that proceeds after FIG. 27.

Referring to FIG. 32, a first contact silicide film 155 may be formed on the first source/drain pattern 150.

Subsequently, a pre-lower conductive contact film 171P may be formed on the first contact silicide film 155. The pre-lower conductive contact film 171P may be formed along the profile of the contact recess 170R, the side wall of the contact hole 170H, and the upper surface of the gate capping pattern 145.

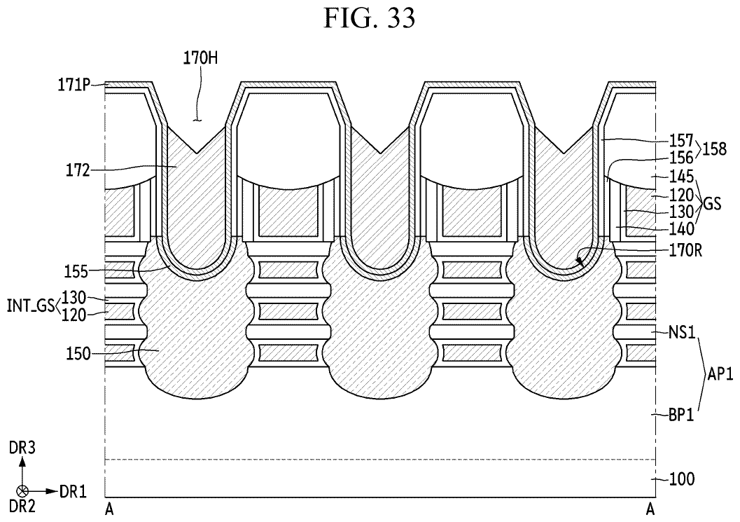

Referring to FIG. 33, a first contact metal pattern 172 may be formed on the pre-lower conductive contact film 171P.

For example, the first contact metal pattern 172 may be formed using a deposition-etch-deposition method. When the first contact metal pattern 172 is formed of molybdenum (Mo), the first contact metal pattern 172 may be formed, using molybdenum pentachloride (MoCl₅) as a precursor. In the deposition-etch-deposition method, the first contact metal pattern 172 is formed and at the same time, a part of the first contact metal pattern 172 may be etched. The thickness of the first contact metal pattern 172 formed at the lower part of the contact hole 170H may be greater than the thickness of the first contact metal pattern 172 formed at the upper part of the contact hole 170H or on the upper surface of the gate capping pattern 145, using such a method. By repeating the above process, the first contact metal pattern 172 may be prevented from being formed on the upper surface of the gate capping pattern 145.

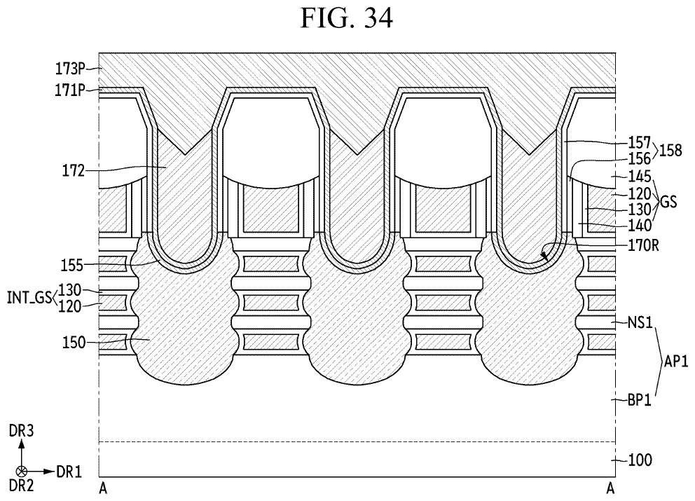

Referring to FIG. 34, the pre-contact metal pattern 173P may be formed on the first contact metal pattern 172.

The pre-contact metal pattern 173P may fill the remainder of the contact hole 170H. The pre-contact metal pattern 173P may be formed on the upper surface of the gate capping pattern 145.

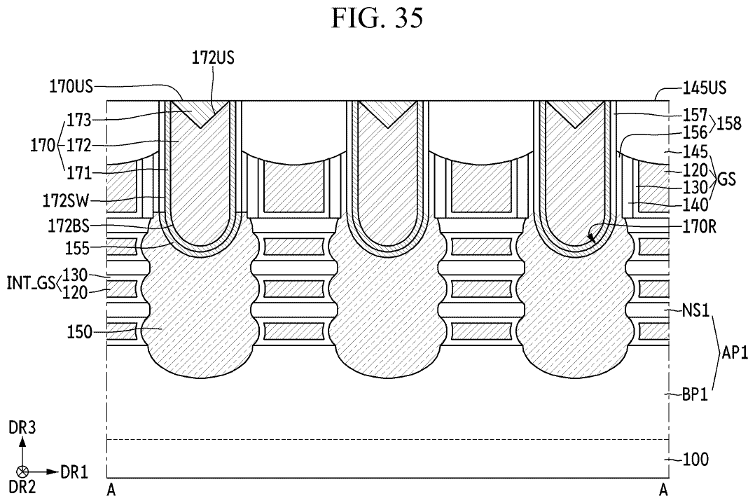

Referring to FIGS. 34 and 35, the pre-contact metal pattern 173P and the pre-lower conductive contact film 171P on the upper surface of the gate capping pattern 145 are removed, and the lower conductive contact pattern 171 and the second contact metal pattern 173 may be formed.

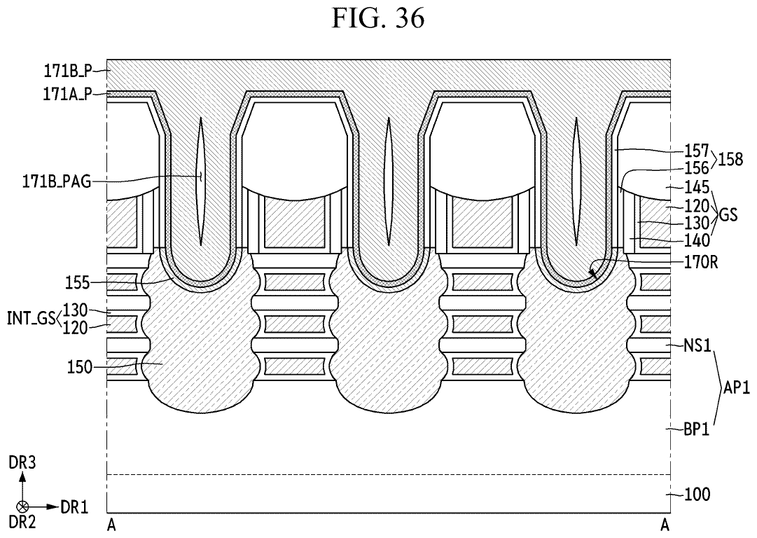

FIGS. 36 to 40 are intermediate stage diagrams for explaining a method for fabricating a semiconductor device according to some implementations. FIG. 36 may be a fabricating process that proceeds after FIG. 27.

Referring to FIG. 36, a first contact silicide film 155 may be formed on the first source/drain pattern 150.

Next, a first pre-lower conductive contact liner 171A_P may be formed on the first contact silicide film 155. The first pre-lower conductive contact liner 171A_P may be formed along the profile of the contact recess 170R, the side wall of the contact hole 170H, and the upper surface of the gate capping pattern 145.

The second pre-lower conductive contact liner 171B_P may be formed on the first pre-lower conductive contact liner 171A_P. The second pre-lower conductive contact liner 171B_P may fill the contact hole 170H. The second pre-lower conductive contact liner 171B_P may be formed on the upper surface of the gate capping pattern 145. The second pre-lower conductive contact liner 171B_P may include a liner air gap 171B_PAG. The liner air gap 171B_PAG may be formed, while the second pre-lower conductive contact liner 171B_P is being formed.

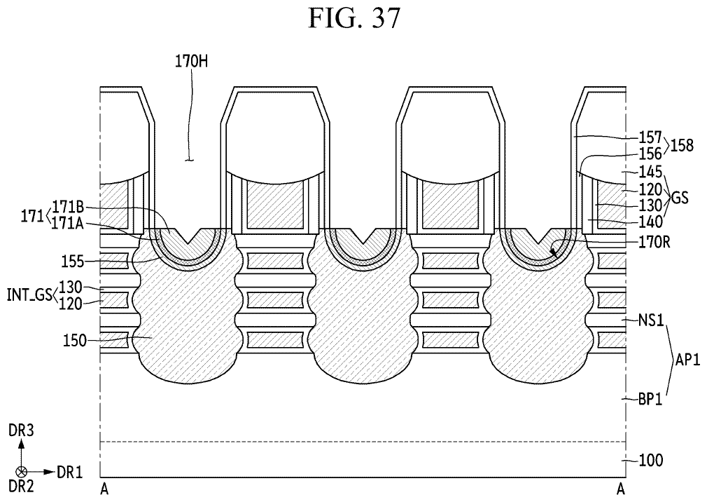

Referring to FIGS. 36 and 37, a part of the first pre-lower conductive contact liner 171A_P and a part of the second pre-lower conductive contact liner 171B_P may be removed, using the anisotropic etching.

Accordingly, the first lower conductive contact liner 171A and the second lower conductive contact liner 171B may be formed.

The lower conductive contact pattern 171 including the first lower conductive contact liner 171A and the second lower conductive contact liner 171B may be formed inside the contact recess 170R.

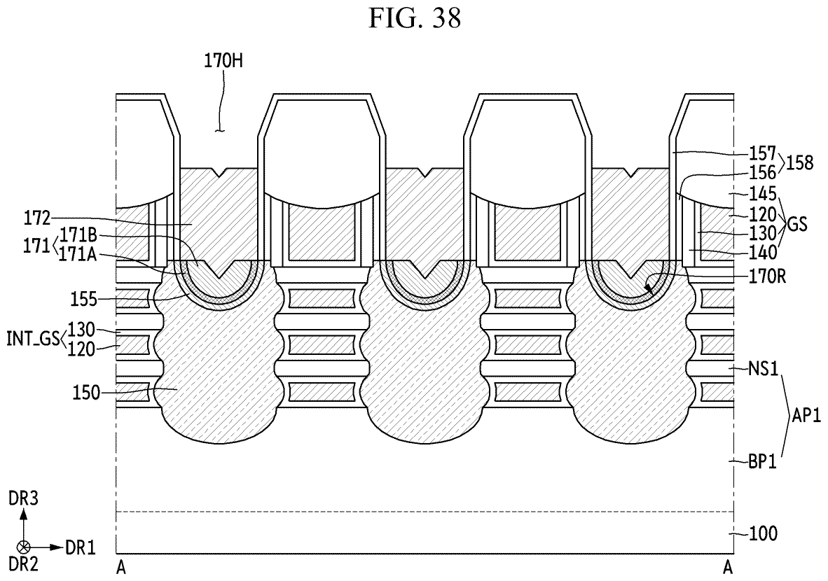

Referring to FIG. 38, a first contact metal pattern 172 may be formed on the first lower conductive contact liner 171A and the second lower conductive contact liner 171B.

The first contact metal pattern 172 may be formed, for example, using a selective chemical vapor deposition method.

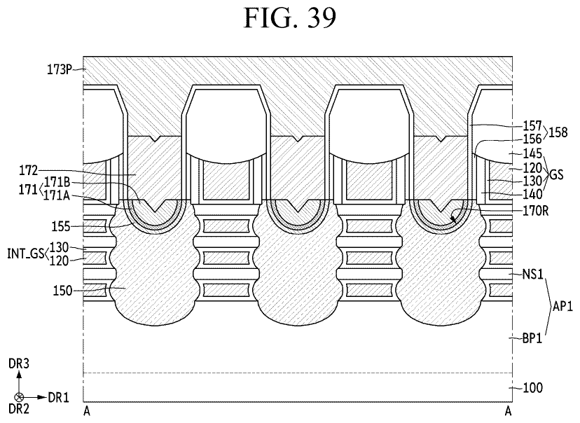

Referring to FIG. 39, a pre-contact metal pattern 173P may be formed on the first contact metal pattern 172.

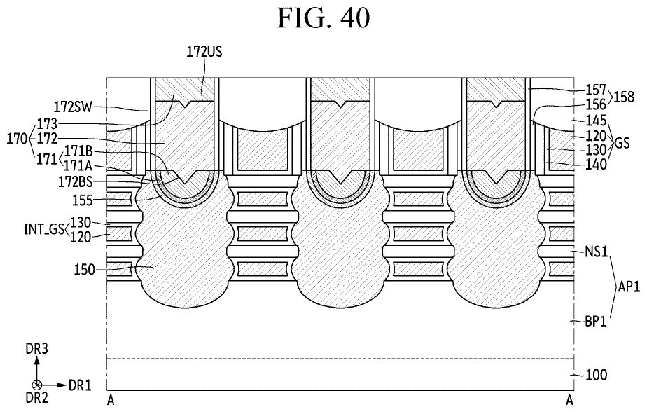

Referring to FIGS. 39 and 40, the pre-contact metal pattern 173P on the upper surface of the gate capping pattern 145 may be removed to form the second contact metal pattern 173.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor device comprising:
a gate structure on an active pattern, wherein the gate structure includes a gate electrode and a gate capping pattern, the gate capping pattern being on the gate electrode;
a source/drain pattern on at least one side of the gate structure;
a contact silicide film on the source/drain pattern, the contact silicide film defining a contact recess;
a source/drain contact that fills the contact recess and is connected to the source/drain pattern;
an etching stop film on an upper surface of the gate capping pattern and an upper surface of the source/drain contact; and
a first via pattern that extends through the etching stop film and is connected to the source/drain contact, wherein the first via pattern comprises a first metal,
wherein the source/drain contact includes a lower conductive contact pattern, a first contact metal pattern that includes a second metal, and a second contact metal pattern that includes a third metal,
wherein the first contact metal pattern and the second contact metal pattern are on the lower conductive contact pattern,
wherein the third metal is different from the first metal and the second metal, and
wherein the second contact metal pattern is between the first contact metal pattern and the first via pattern, and the second contact metal pattern is in contact with the first via pattern.

2. The semiconductor device of claim 1, comprising:
a source/drain etching liner extending along a side wall of the gate structure,
wherein the first contact metal pattern is in contact with the source/drain etching liner.

3. The semiconductor device of claim 2,
wherein the lower conductive contact pattern comprises a fourth metal and is in contact with the contact silicide film.

4. The semiconductor device of claim 2,
wherein the lower conductive contact pattern includes a first lower conductive contact liner that is in contact with the contact silicide film, and a second lower conductive contact liner that is between the first lower conductive contact liner and the first contact metal pattern, and
wherein the second lower conductive contact liner comprises a fourth metal and is in contact with the first contact metal pattern.

5. The semiconductor device of claim 1,
wherein the first contact metal pattern includes side walls that face the gate electrode, and
wherein the lower conductive contact pattern extends along a profile of the contact recess and the side walls of the first contact metal pattern.

6. The semiconductor device of claim 1,
wherein each of the first metal and the second metal includes molybdenum.

7. The semiconductor device of claim 6,
wherein the third metal includes tungsten.

8. The semiconductor device of claim 1,
wherein the second contact metal pattern includes at least a part of an upper surface of the source/drain contact.

9. The semiconductor device of claim 1, comprising:
a gate contact that extends through the etching stop film and the gate capping pattern, wherein the gate contact is connected to the gate electrode.

10. The semiconductor device of claim 1, comprising:
a gate contact inside the gate capping pattern; and
a second via pattern that extends through the etching stop film and is connected to the gate contact.

11. The semiconductor device of claim 1,
wherein the active pattern includes a lower pattern and a sheet pattern on the lower pattern, and
wherein the gate electrode surrounds the sheet pattern.

12. A semiconductor device comprising:
a gate structure on an active pattern, wherein the gate structure includes a gate electrode and a gate capping pattern, the gate capping pattern being on the gate electrode;
a source/drain pattern on at least one side of the gate structure;
a source/drain contact that is on the source/drain pattern and connected to the source/drain pattern; and
a molybdenum via pattern on the source/drain contact, and the molybdenum via pattern being in contact with an upper surface of the source/drain contact,
wherein the source/drain contact includes a lower conductive contact pattern, a contact metal pattern that includes a first metal, and a tungsten contact pattern,
wherein the contact metal pattern is between the tungsten contact pattern and the lower conductive contact pattern, and
wherein at least a part of an upper surface of the source/drain contact is defined by the tungsten contact pattern.

13. The semiconductor device of claim 12,
wherein the first metal is molybdenum.

14. The semiconductor device of claim 12, comprising:
a source/drain etching liner extending along a side wall of the gate structure,
wherein the contact metal pattern is in contact with the source/drain etching liner.

15. The semiconductor device of claim 14, comprising:
a contact silicide film between the source/drain contact and the source/drain pattern,
wherein the lower conductive contact pattern comprises a second metal different from the first metal, and the lower conductive contact pattern is in contact with the contact silicide film.

16. The semiconductor device of claim 14, comprising:
a contact silicide film between the source/drain contact and the source/drain pattern,
wherein the lower conductive contact pattern includes a first lower conductive contact liner that is in contact with the contact silicide film, and a second lower conductive contact liner that is between the first lower conductive contact liner and the contact metal pattern,
wherein the second lower conductive contact liner comprises a second metal and is in contact with the contact metal pattern, and
wherein the second metal is one of tungsten or molybdenum.

17. The semiconductor device of claim 12, comprising:
a contact silicide film that is between the source/drain contact and the source/drain pattern and defines a contact recess,
wherein the contact metal pattern includes a side wall that faces a gate electrode, and
wherein the lower conductive contact pattern extends along a profile of the contact recess and the side wall of the contact metal pattern.

18. A semiconductor device comprising:
an active pattern that includes a lower pattern and a sheet pattern on the lower pattern;
a gate structure that includes a gate electrode and a gate capping pattern on the active pattern, the gate electrode surrounding the sheet pattern, and the gate capping pattern being on the gate electrode;
a source/drain pattern on at least one side of the gate structure;
a source/drain contact connected to the source/drain pattern, the source/drain contact being on the source/drain pattern;
an etching stop film that is on an upper surface of the gate capping pattern and an upper surface of the source/drain contact; and
a molybdenum via pattern that extends through the etching stop film and is in contact with the upper surface of the source/drain contact,
wherein the source/drain contact includes a lower conductive contact pattern, a molybdenum contact pattern, and a tungsten contact pattern, and
wherein at least a part of the upper surface of the source/drain contact is defined by the tungsten contact pattern.

19. The semiconductor device of claim 18, comprising:
a source/drain etching liner that extends along a side wall of the gate structure,
wherein the molybdenum contact pattern is in contact with the source/drain etching liner.

20. The semiconductor device of claim 18, comprising:
a contact silicide film between the source/drain contact and the source/drain pattern,
wherein the lower conductive contact pattern comprises tungsten and is in contact with the contact silicide film.
